(19) United States
(12) Patent Application Publication
(10) Pub. No.: US 2024/0105834 A1
(43) Pub. Date: Mar. 28, 2024

(54) SEMICONDUCTOR DEVICE

(71) Applicant: ROHM CO., LTD., Kyoto (JP)

(72) Inventors: Hajime OKUDA, Kyoto (JP); Yoshinori FUKUDA, Kyoto (JP); Adrian JOITA, Kyoto (JP); Toru TAKUMA, Kyoto (JP)

(73) Assignee: ROHM CO., LTD., Kyoto (JP)

(21) Appl. No.: 18/466,322

(22) Filed: Sep. 13, 2023

(30) Foreign Application Priority Data
Sep. 26, 2022 (JP) 2022-152202

(51) Int. Cl. H01L 29/78; H01L 27/06; H01L 29/06; H01L 29/423

(52) U.S. Cl. CPC H01L 29/7813; H01L 27/0629; H01L 29/0607; H01L 29/42368; H01L 29/42376

(57) ABSTRACT

A semiconductor device includes: a semiconductor region of a first conductivity type having a main surface; a capacitor region of a second conductivity type formed in a surface layer portion of the main surface; and at least one trench structure including a trench formed in the main surface to penetrate the capacitor region, an insulating film covering a wall surface of the trench, and embedded electrodes embedded in the trench so as to form capacitive coupling with the capacitor region through the insulating film.

### CROSS-REFERENCE TO RELATED APPLICATION

This application is based upon and claims the benefit of priority from Japanese Patent Application No. 2022-152202, filed on Sep. 26, 2022, the entire contents of which are incorporated herein by reference.

### TECHNICAL FIELD

The present disclosure relates to a semiconductor device.

### BACKGROUND

In the related art, there is known a semiconductor device including a MOSFET and a capacitor. This semiconductor device includes an n-type semiconductor substrate, a trench, a capacitive insulating film, a trench source electrode, a p-type impurity region, a source electrode, and a drain electrode on the capacitor side. The semiconductor substrate has a front surface and a back surface. The trench is formed on the front surface of the semiconductor substrate. The capacitive insulating film covers the wall surface of the trench.

The trench source electrode is embedded in the trench and disposed between portions of the capacitive insulating film. The impurity region is formed in a region provided along the trench in the surface layer portion of the semiconductor substrate. The source electrode is electrically connected to the trench source electrode and the impurity region on the front surface of the semiconductor substrate to fix the trench source electrode and the impurity region to the same electric potential. The drain electrode is electrically connected to the back surface of the semiconductor substrate.

The capacitor is formed by the semiconductor substrate, the trench source electrode, and the capacitive insulating film disposed between the semiconductor substrate and the trench source electrode, and is electrically installed and disposed between the source and drain of the MOSFET. That is, the trench source electrode is capacitively coupled to the semiconductor substrate and is not capacitively coupled to the impurity region.

### BRIEF DESCRIPTION OF DRAWINGS

The accompanying drawings, which are incorporated in and constitute a part of the specification, illustrate embodiments of the present disclosure.

FIG. 1 is a plan view showing an embodiment of a semiconductor device.

FIG. 2 is a cross-sectional view taken along line II-II in FIG. 1.

FIG. 3 is a schematic circuit diagram showing an electrical configuration of the semiconductor device shown in FIG. 1.

FIG. 4 is a schematic circuit diagram showing a configuration of an output transistor.

FIG. 5 is a circuit diagram showing a part of a gate control circuit shown in FIG. 3.

FIG. 6 is a plan view showing a transistor region shown in FIG. 1.

FIG. 7 is an enlarged plan view showing a main part of the transistor region shown in FIG. 6.

FIG. 8 is an enlarged plan view showing another main part of the transistor region shown in FIG. 6.

FIG. 9 is a cross-sectional view taken along line IX-IX in FIG. 7.

FIG. 10 is a cross-sectional view taken along line X-X in FIG. 7.

FIG. 11 is a cross-sectional view taken along line XI-XI in FIG. 7.

FIG. 12 is a cross-sectional view taken along line XII-XII in FIG. 7.

FIG. 13 is a cross-sectional view taken along line XIII-XIII in FIG. 7.

FIG. 14 is a plan view showing a capacitive device region shown in FIG. 1.

FIG. 15 is an enlarged plan view showing a main part of the capacitive device region shown in FIG. 14.

FIG. 16 is an enlarged plan view showing another main part of the capacitive device region shown in FIG. 14.

FIG. 17 is a cross-sectional view taken along line XVII-XVII in FIG. 15.

FIG. 18 is a cross-sectional view taken along line XVIII-XVIII in FIG. 15.

FIG. 19 is a cross-sectional view taken along line XIX-XIX in FIG. 15.

FIG. 20 is a cross-sectional view taken along line XX-XX in FIG. 15.

FIG. 21 is a comparative cross-sectional view of the transistor region and the capacitive device region.

FIG. 22 is a graph showing capacitance characteristics of a capacitor.

FIG. 23 is a cross-sectional view showing a first modification of the transistor region.

FIG. 24 is a plan view showing a second modification of the transistor region.

FIG. 25 is a plan view showing a first modification of the capacitive device region.

FIG. 26 is a plan view showing a second modification of the capacitive device region.

FIG. 27 is an enlarged plan view showing a main part of the capacitive device region shown in FIG. 26.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments will now be described in detail with reference to the accompanying drawings. The attached drawings are schematic diagrams and are not strictly illustrated. The scales and the like do not necessarily match. In addition, the same reference numerals are given to structures corresponding to each other in the accompanying drawings, and duplicate descriptions are omitted or simplified. For the structures whose descriptions are omitted or simplified, the descriptions given before the omissions or simplifications apply.

When the phrase “substantially equal” is used in a description with a comparison target, the phrase includes not only a numerical value (form) equal to the numerical value (form) of the comparison target, but also a numerical value error (form error) within a range of ±10% based on the numerical value (form) of the comparison target. Although words such as “first,” “second,” “third,” and the like are used in the embodiments, these are symbols attached to the names of the respective structures to clarify the order of description, and are not intended to limit the names of the respective structures.

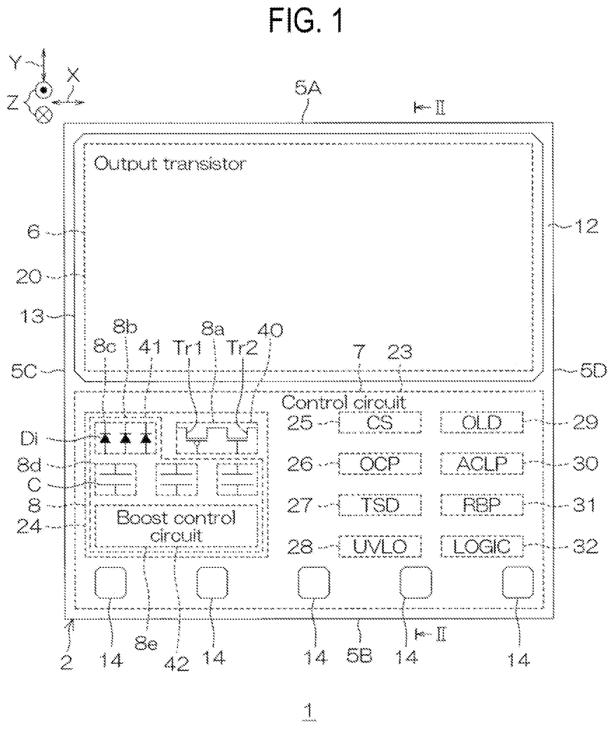

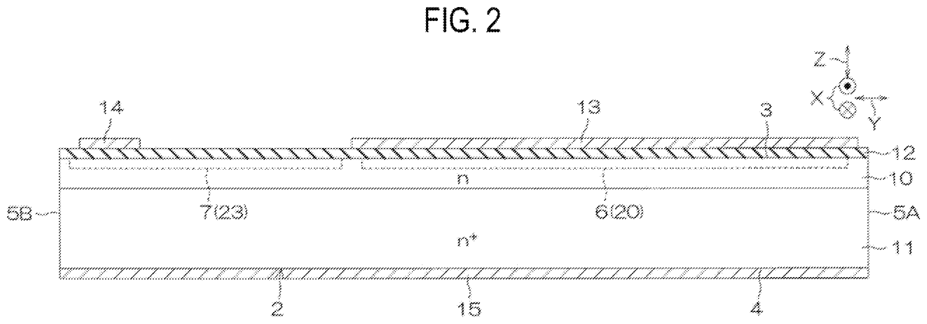

FIG. 1 is a plan view showing an embodiment of a semiconductor device 1. FIG. 2 is a cross-sectional view taken along line II-II in FIG. 1. Referring to FIGS. 1 and 2, the semiconductor device 1 includes a chip 2 formed in a rectangular parallelepiped shape. In this embodiment, the chip 2 is a Si chip containing monocrystalline Si.

Of course, the chip 2 may include a wide bandgap semiconductor chip containing a wide bandgap semiconductor single crystal. The wide bandgap semiconductor is a semiconductor having a bandgap larger than that of Si. GaN (gallium nitride), SiC (silicon carbide), C (diamond), and the like are exemplified as wide bandgap semiconductors. For example, the chip 2 may be a SiC chip containing a SiC single crystal.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are formed in a quadrangular shape in a plan view viewed from a normal direction Z (hereinafter simply referred to as “in a plan view”). The normal direction Z is also the thickness direction of the chip 2.

The first main surface 3 is a circuit surface on which various circuit structures forming an electronic circuit are formed. The second main surface 4 is a non-circuit surface having no circuit structure. The first side surface 5A and the second side surface 5B extend in a first direction X along the first main surface 3 and face (oppose) each other in a second direction Y intersecting (specifically, orthogonal to) the first direction X. The third side surface 5C and the fourth side surface 5D extend in the second direction Y and face (oppose) each other in the first direction X.

The semiconductor device 1 includes a transistor region 6 provided on the first main surface 3. The transistor region 6 is a region (output region) that includes a trench gate type transistor and generates an output signal to be outputted to the outside. In this embodiment, the transistor region 6 is defined in the region on the first side surface 5A side on the first main surface 3. The transistor region 6 is defined in a polygonal shape (quadrangular shape in this embodiment) having four sides parallel to the peripheral edge of the first main surface 3 in a plan view.

The position, size, plan-view shape, and the like of the transistor region 6 are arbitrary and are not limited to a specific layout. The transistor region 6 may have a plan-view area of 25% or more and 80% or less of the plan-view area of the first main surface 3. The plan-view area of the transistor region 6 may be 30% or more of the plan-view area of the first main surface 3. The plan-view area of the transistor region 6 may be 40% or more of the plan-view area of the first main surface 3. The plan-view area of the transistor region 6 may be 50% or more of the plan-view area of the first main surface 3. The plan-view area of the transistor region 6 may be 75% or less of the plan-view area of the first main surface 3.

The semiconductor device 1 includes a control region 7 provided in a region different from the transistor region 6 on the first main surface 3. The control region 7 is a region having a plurality of types of electronic circuits (circuit devices) that realize various functions. In this embodiment, the control region 7 is defined in a region on the second side surface 5B side with respect to the transistor region 6 and faces the transistor region 6 in the second direction Y. In this embodiment, the control region 7 is defined in a polygonal shape (quadrangular shape in this embodiment) having four sides parallel to the peripheral edge of the first main surface 3 in a plan view.

The position, size, plan-view shape, and the like of the control region 7 are arbitrary and are not limited to a specific layout. The control region 7 may have a plan-view area of 25% or more and 80% or less of the plan-view area of the first main surface 3. The plan-view area of the control region 7 may be 30% or more of the plan-view area of the first main surface 3. The plan-view area of the control region 7 may be 40% or more of the plan-view area of the first main surface 3. The plan-view area of the control region 7 may be 50% or more of the plan-view area of the first main surface 3. The plan-view area of the control region 7 may be 75% or less of the plan-view area of the first main surface 3.

The plan-view area of the control region 7 may be substantially equal to the plan-view area of the transistor region 6. The plan-view area of the control region 7 may be larger than the plan-view area of the transistor region 6. The plan-view area of the control region 7 may be smaller than the plan-view area of the transistor region 6. The ratio of the plan-view area of the control region 7 to the plan-view area of the transistor region 6 may be 0.1 or more and 4 or less.

The control region 7 includes a gate control region 8. The gate control region 8 is a region including a plurality of electronic circuits (circuit devices) configured to generate gate signals that control the transistor region 6. In this embodiment, the gate control region 8 includes a CMIS (Complementary Metal Insulator Semiconductor) region 8a and a boost region 8b.

The CMIS region 8a is a region that generates a gate signal and applies the gate signal to the transistor region 6. The CMIS region 8a includes a first planar gate/p-channel transistor Tr1 and a second planar gate/n-channel transistor Tr2. The position, size, plan-view shape, and the like of the CMIS region 8a are arbitrary, and are not limited to a specific layout. In this embodiment, the CMIS region 8a is arranged inside the control region 7.

The CMIS region 8a may have a plan-view area smaller than that of the transistor region 6. The plan-view area of the CMIS region 8a may be 1/10 or less of the plan-view area of the transistor region 6. The plan-view area of the CMIS region 8a may be 1/25 or less of the plan-view area of the transistor region 6. The plan-view area of the CMIS region 8a may be 1/50 or less of the plan-view area of the transistor region 6. The plan-view area of the CMIS region 8a may be 1/100 or less of the plan-view area of the transistor region 6.

The boost region 8b includes a boost circuit and generates a boosted voltage in response to an input voltage from the outside and applies the boosted voltage to the CMIS region 8a. Specifically, the boost circuit is a charge pump circuit. The boost region 8b may be referred to as a “charge pump circuit region.”

In this embodiment, the boost region 8b includes at least one (one in this embodiment) rectifying device region 8c, at least one (a plurality of, in this embodiment) capacitive device region 8d, and a boost control region 8e. The rectifying device region 8c may be referred to as an “active device region” and the capacitive device region 8d may be referred to as a “passive device region.”

The rectifying device region 8c is a region having at least one (a plurality of, in this embodiment) diode Di (first to third diodes Di1 to Di3). The position, size, plan-view shape, and the like of the rectifying device region 8c are arbitrary and are not limited to a specific layout. The rectifying device region 8c may have a plan-view area smaller than that of the transistor region 6. In this embodiment, the rectifying device region 8c is arranged at the peripheral edge portion of the control region 7 (around the CMIS region 8a) so as to be adjacent to the CMIS region 8a.

The plan-view area of the rectifying device region 8c may be 1/10 or less of the plan-view area of the transistor region 6. The plan-view area of the rectifying device region 8c may be 1/25 or less of the plan-view area of the transistor region 6. The plan-view area of the rectifying device region 8c may be 1/50 or less of the plan-view area of the transistor region 6. The plan-view area of the rectifying device region 8c may be 1/100 or less of the plan-view area of the transistor region 6.

Each capacitive device region 8d is a region having at least one (one in this embodiment) capacitor C (first capacitors C1 to C3). The position, size, plan-view shape, and the like of each capacitive device region 8d are appropriately adjusted according to the capacitance value to be achieved, and are not limited to a specific layout. In this embodiment, each capacitive device region 8d is arranged in the peripheral edge portion of the control region 7 (around the rectifying device region 8c) so as to be adjacent to the rectifying device region 8c.

Each capacitive device region 8d may have a plan-view area smaller than that of the transistor region 6. The plan-view area of each capacitive device region 8d may be 1/10 or less of the plan-view area of the transistor region 6. The plan-view area of each capacitive device region 8d is 1/25 or less of the plan-view area of the transistor region 6. The plan-view area of each capacitive device region 8d may be 1/50 or less of the plan-view area of the transistor region 6. The plan-view area of each capacitive device region 8d may be 1/100 or less of the plan-view area of the transistor region 6.

The capacitor C in each capacitive device region 8d is controlled by a capacitor voltage (inter-terminal voltage) of 1 V or more and 10 V or less. The capacitor voltage may be 1 V or more and 2.5 V or less, 2.5 V or more and 5 V or less, 5 V or more and 7.5 V or less, or 7.5 V or more and 10 V or less. The capacitor voltage may be 2 V or more and 6 V or less.

The capacitor C may have a capacitance value of 10 pF or more and 100 pF or less per 10,000 μm². The capacitance value at 10,000 μm² may be 10 pF or more and 25 pF or less, 25 pF or more and 50 pF or less, 50 pF or more and 75 pF or less, or 75 pF or more and 100 pF or less. The capacitance value at 10,000 μm² may be 25 pF or more and 60 pF or less.

The boost control region 8e is a region having an electronic circuit configured to generate an electrical signal applied to at least one (a plurality of, in this embodiment) capacitive device region 8d (capacitors C). The position, size, plan-view shape, and the like of the boost control region 8e are arbitrary, and are not limited to a specific layout. The boost control region 8e is arranged at the peripheral edge portion of the control region 7 so as to be adjacent to the rectifying device region 8c and/or at least one capacitive device region 8d. The boost control region 8e may have a plan-view area smaller than that of the transistor region 6.

The semiconductor device 1 includes an n-type first semiconductor region 10 formed in the surface layer portion of the first main surface 3. The first semiconductor region 10 may also be referred to as a “drift region” or a “drain region.” The n-type impurity concentration of the first semiconductor region 10 may be 1×10¹⁵ cm⁻³ or more and 1×10¹⁸ cm⁻³ or less.

The first semiconductor region 10 is formed in a layer shape extending along the first main surface 3 in the transistor region 6 and the control region 7 (capacitive device region 8d). Specifically, the first semiconductor region 10 is formed in a layer shape extending along the first main surface 3 over the entire surface layer portion of the first main surface 3, and is exposed from the first main surface 3 and the first to fourth side surfaces 5A to 5D.

The thickness of the first semiconductor region 10 may be 1 μm or more and 20 μm or less. The thickness of the first semiconductor region 10 may be 5 μm or more and 15 μm or less. The thickness of the first semiconductor region 10 may be 10 μm or less. In this embodiment, the first semiconductor region 10 is formed of an n-type epitaxial layer (Si epitaxial layer).

The semiconductor device 1 includes an n-type (first conductivity type) second semiconductor region 11 formed in the surface layer portion of the second main surface 4. The second semiconductor region 11 may be referred to as a “drain region.” The second semiconductor region 11 has a higher n-type impurity concentration than the first semiconductor region 10. The n-type impurity concentration of the second semiconductor region 11 may be 1×10¹⁸ cm⁻³ or more and 1×10²¹ cm⁻³ or less. The second semiconductor region 11 is formed in a layer shape extending along the second main surface 4 over the entire surface layer portion of the second main surface 4, and is exposed from the second main surface 4 and the first to fourth side surfaces 5A to 5D.

The second semiconductor region 11 is electrically connected to the first semiconductor region 10 inside the chip 2. The second semiconductor region 11 has a thickness greater than the thickness of the first semiconductor region 10. The second semiconductor region 11 may have a thickness of 50 μm or more and 200 μm or less. The thickness of the second semiconductor region 11 may be 150 μm or less. In this embodiment, the second semiconductor region 11 is formed of an n-type semiconductor substrate (Si substrate).

The semiconductor device 1 includes an interlayer insulating layer 12 covering the first main surface 3. The interlayer insulating layer 12 collectively covers the transistor region 6, the control region 7, and the boost region 8b. The interlayer insulating layer 12 may cover the entire first main surface 3 so as to be contiguous with the peripheral edge of the first main surface 3 (first to fourth side surfaces 5A to 5D).

In this embodiment, the interlayer insulating layer 12 is formed of a multilayer wiring structure having a laminated structure in which a plurality of insulating layers and a plurality of wiring layers are alternately laminated. Each insulating layer may include at least one of a silicon oxide film or a silicon nitride film. Each wiring layer may include at least one of a pure Al layer (an Al layer with a purity of 99% or higher), a Cu layer (a Cu layer with a purity of 99% or higher), an AlCu alloy layer, an AlSiCu alloy layer, and an AlSi alloy layer.

The semiconductor device 1 includes a plurality of terminals 13 to 15 arranged on one or both (both in this embodiment) of the first main surface 3 and the second main surface 4. The plurality of terminals 13 to 15 includes a source terminal 13, a plurality of control terminals 14, and a drain terminal 15.

In this embodiment, the source terminal 13 is provided as an output terminal electrically connected to a load, and is arranged on a portion of the interlayer insulating layer 12 covering the transistor region 6. The source terminal 13 may cover the entire transistor region 6 in a plan view. The source terminal 13 may include at least one of a pure Al layer, a Cu layer, an AlCu alloy layer, an AlSiCu alloy layer, and an AlSi alloy layer.

A plurality of control terminals 14 are electrically connected to various electronic circuits in the control region 7, and are arranged on a portion of the interlayer insulating layer 12 covering the control region 7. Each of the plurality of control terminals 14 has a plan-view area smaller than the plan-view area of the source terminal 13. The plurality of control terminals 14 are arranged at intervals along the peripheral edge portion of the control region 7 (the peripheral edge portion of the first main surface 3).

The plurality of control terminals 14 are arranged so as to expose the capacitive device regions 8d in a plan view. The plurality of control terminals 14 are arranged so as to expose the rectifying device region 8c in a plan view. The plurality of control terminals 14 are arranged so as to expose the CMIS region 8a in a plan view. The plurality of control terminals 14 are arranged so as to expose the boost region 8b in a plan view. The plurality of control terminals 14 are arranged so as to expose the gate control region 8 in a plan view.

The plan-view area of each control terminal 14 is set to fall within a range in which a bonding wire can be connected. The plan-view area of each control terminal 14 may be 1/10 or less of the plan-view area of the source terminal 13. The plurality of control terminals 14 may include at least one of a pure Al layer, a Cu layer, an AlCu alloy layer, an AlSiCu alloy layer, or an AlSi alloy layer.

In this embodiment, the drain terminal 15 is provided as a power supply terminal to directly cover the second main surface 4 of the chip 2. That is, in this embodiment, the semiconductor device is a high-side switching device electrically disposed between the power source and the load. The drain terminal 15 is electrically connected to the second semiconductor region 11 on the second main surface 4. The drain terminal 15 covers the entire second main surface 4 so as to be continuous with the peripheral edge of the second main surface 4 (first to fourth side surfaces 5A to 5D).

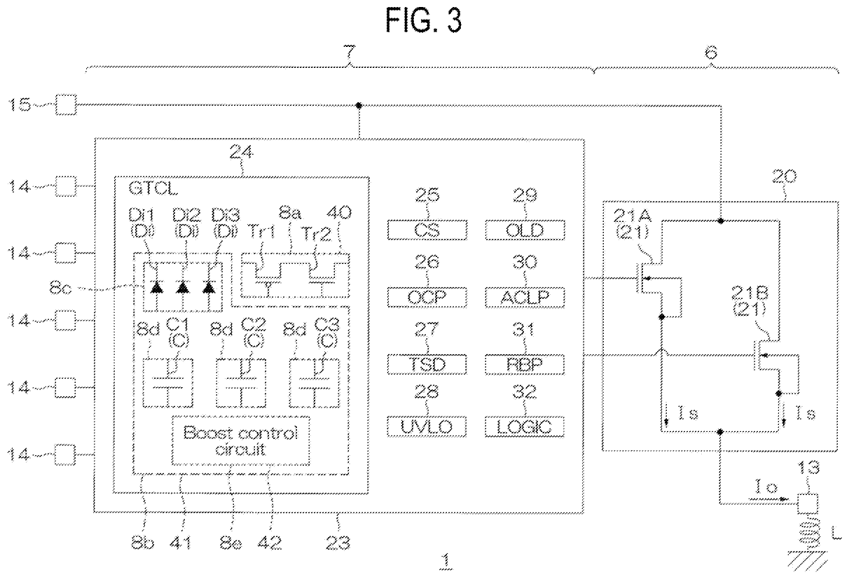

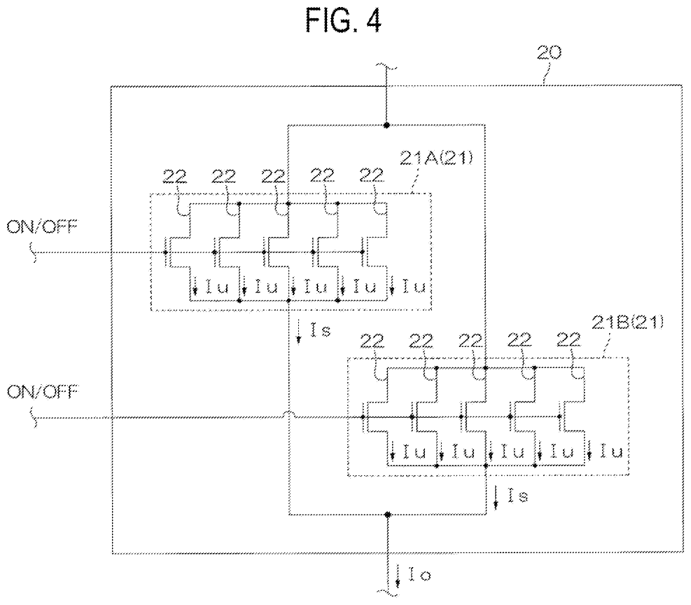

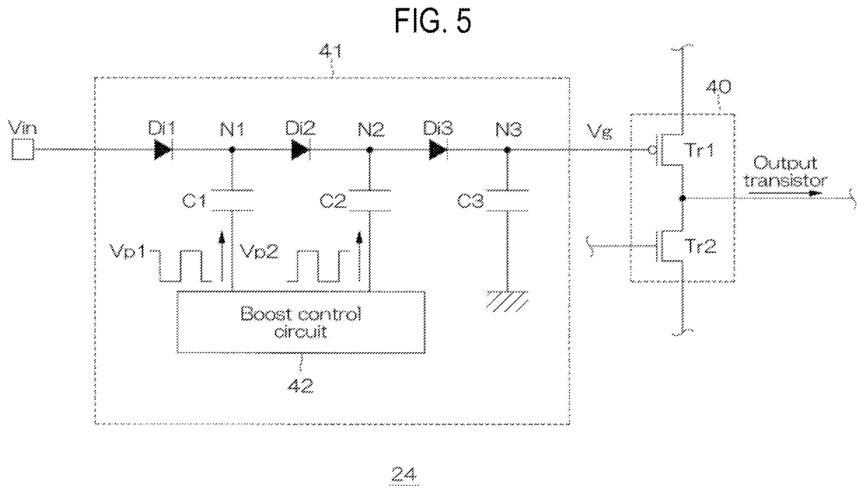

FIG. 3 is a schematic circuit diagram showing an electrical configuration of the semiconductor device 1 shown in FIG. 1. FIG. 4 is a schematic circuit diagram showing a configuration of the output transistor 20. FIG. 5 is a circuit diagram showing a part of a gate control circuit 24 shown in FIG. 3.

In order to show an operation example of the semiconductor device 1, FIG. 3 shows an example in which an inductive load L as an example of a load is electrically connected to the source terminal 13. The inductive load L is not a component of the semiconductor device 1. Therefore, the configuration including the semiconductor device 1 and the inductive load L may be referred to as an “inductive load driving device” or an “inductive load control device.” Examples of the inductive load L include a relay, a solenoid, a lamp, a motor, and the like. The inductive load L may be a vehicle-mounted inductive load. That is, the semiconductor device 1 may be a vehicle-mounted semiconductor device.

Referring to FIGS. 3 and 4, the semiconductor device 1 includes an output transistor 20 formed in the transistor region 6. In this embodiment, the output transistor 20 includes a gate split transistor including one main drain, one main source, and a plurality of main gates. The main drain is electrically connected to the drain terminal 15. The main source is electrically connected to the source terminal 13.

The main gates are configured to individually receive a plurality of electrically independent gate signals (gate electric potentials). The output transistor 20 generates a single output current Io (output signal) in response to the plurality of gate signals. In other words, the output transistor 20 includes a multi-input single-output switching device. The output current Io is a drain-source current that flows between the main drain and the main source. The output current Io is outputted to the outside of the chip 2 (the inductive load L) via the source terminal 13.

The output transistor 20 includes a plurality of (two or more) electrically independently controlled system transistors 21. In this embodiment, the system transistors 21 include a first system transistor 21A and a second system transistor 21B. The system transistors 21 are collectively formed in the transistor region 6. The system transistors 21 are connected in parallel so that a plurality of gate signals are individually inputted thereto. The system transistors 21 are configured so that the system transistor 21 in an on state and the system transistor 21 in an off state coexist.

The system transistors 21 include system drains, system sources, and system gates. The system drains are electrically connected to the main drain (drain terminal 15). The system sources are electrically connected to the main source (source terminal 13). Each system gate is electrically connected to each main gate. In other words, each system gate constitutes each main gate.

Each of the system transistors 21 generates a system current Is in response to the corresponding gate signal. The system current Is is a drain-source current that flows between the system drain and the system source of each of the system transistors 21. A plurality of system currents Is may have different values or substantially equal values. The system currents Is are summed between the main drain and the main source. As a result, a single output current Io which is a sum of a plurality of system currents Is is generated.

Referring to FIG. 4, each of the system transistors 21 includes a single or a plurality of unit transistors 22 systematized (grouped) as individual control targets. Specifically, the system transistors 21 may be a parallel circuit including a single unit transistor 22 or a plurality of unit transistors 22. In this embodiment, each of the unit transistors 22 is of a trench gate vertical type. The system transistors 21 may include the same number of unit transistors 22 or may include different numbers of unit transistors 22.

Each unit transistor 22 includes a unit drain, a unit source, and a unit gate. The unit drain of each unit transistor 22 is electrically connected to the system drain of the corresponding system transistor 21. The unit source of each unit transistor 22 is electrically connected to the system source of the corresponding system transistor 21. The unit gate of each unit transistor 22 is electrically connected to the system gate of the corresponding system transistor 21.

Each of the unit transistors 22 generates a unit current Iu in response to the corresponding gate signal. Each unit current Iu is a drain-source current flowing between the unit drain and the unit source of each unit transistor 22. The unit currents Iu may have different values or substantially equal values. The unit currents Iu are summed between the corresponding system drain and system source. As a result, a system current Is which is a sum of a plurality of unit currents Iu is generated.

In this way, the output transistor 20 is configured such that the first system transistor 21A and the second system transistor 21B are controlled to be turned on and off electrically independent of each other. That is, the output transistor 20 is configured such that both the first system transistor 21A and the second system transistor 21B are turned on at the same time. Further, the output transistor 20 is configured such that one of the first system transistor 21A and the second system transistor 21B is turned on and the other is turned off.

When both the first system transistor 21A and the second system transistor 21B are turned on at the same time, the channel utilization rate of the output transistor 20 increases and the on-resistance decreases. When one of the first system transistor 21A and the second system transistor 21B is turned on while the other is turned off, the channel utilization rate of the output transistor 20 decreases and the on-resistance increases. In other words, the output transistor 20 may be an on-resistance variable switching device.

The semiconductor device 1 includes a control circuit 23 formed in the control region 7 so as to be electrically connected to the output transistor 20. The control circuit 23 may be referred to as a “control IC.” The control circuit 23 includes various functional circuits and forms an IPD (Intelligent Power Device) together with the output transistor 20. The IPD may also be referred to as an “IPM (Intelligent Power Module),” “IPS (Intelligent Power Switch),” “smart power driver,” “smart MISFET (smart MOSFET),” or “protected MISFET (protected MOSFET).”

In this embodiment, the control circuit 23 includes a gate control circuit 24, a current monitor circuit 25, an overcurrent protection circuit 26, an overheat protection circuit 27, a low voltage malfunction avoidance circuit 28, an open load detection circuit 29, an active clamp circuit 30, a power source reverse connection protection circuit 31, and a logic circuit 32. The control circuit 23 does not necessarily need to include all of these functional circuits at the same time, and may include at least one of these functional circuits.

The current monitor circuit 25 may be referred to as a CS circuit (current sense circuit). The overcurrent protection circuit 26 may be referred to as an OCP circuit (over current protection circuit). The overheat protection circuit 27 may be referred to as a TSD circuit (thermal shutdown circuit). The low voltage malfunction avoidance circuit 28 may be referred to as a UVLO circuit (under voltage lock out circuit). The open load detection circuit 29 may be referred to as an OLD circuit (open load detection circuit). The power source reverse connection protection circuit 31 may be referred to as an RBP circuit (reverse battery protection circuit).

The gate control circuit 24 is formed in the gate control region 8 and configured to generate a gate signal for controlling the on/off of the output transistor 20. Specifically, the gate control circuit 24 generates a plurality of gate signals for individually controlling the on/off of the system transistors 21.

That is, in this embodiment, the gate control circuit 24 generates a first gate signal for individually controlling the on/off of the first system transistor 21A, and a second gate signal for individually controlling the on/off of the second system transistor 21B electrically independently of the first system transistor 21A. An example circuit for generating one gate signal will be described below.

Referring to FIGS. 1, 3, and 5, the gate control circuit 24 includes a CMIS circuit 40 and a boost circuit 41. The boost circuit 41 may be referred to as a “charge pump circuit.” The CMIS circuit 40 is formed in the CMIS region 8a. The CMIS circuit 40 is a series circuit including a p-channel first transistor Tr1 and an n-channel second transistor Tr2.

The first transistor Tr1 is arranged on a high electric potential side (high side), and the second transistor Tr2 is arranged on a low electric potential side (low side). A node portion between the first transistor Tr1 and the second transistor Tr2 is electrically connected to one main gate of the output transistor 20.

The boost circuit 41 is electrically connected to the first transistor Tr1 as a voltage source for the gate of the first transistor Tr1. The boost circuit 41 boosts the input voltage Vin to generate a predetermined control voltage Vg (boosted voltage) and outputs the control voltage Vg to the gate of the first transistor Tr1. Although not shown, the control voltage Vg is applied to the gate of the second transistor Tr2 from another voltage source. As a result, the first transistor Tr1 and the second transistor Tr2 are alternately on/off controlled to generate a gate signal. For example, the input voltage Vin may be a power source voltage.

In this embodiment, the boost circuit 41 is a ladder circuit including a plurality of diodes Di (first to third diodes Di1 to Di3), a plurality of capacitors C (first to third capacitors C1 to C3), and a boost control circuit 42. The first to third diodes Di1 to Di3 are formed in the rectifying device region 8c. Each of the first to third diodes Di1 to Di3 has an anode portion and a cathode portion.

The anode portion of the first diode Di1 is electrically connected to the input terminal (drain terminal 15) that receives a non-boosted input voltage Vin. The anode portion of the second diode Di2 is electrically connected to the cathode portion of the first diode Di1 to form a first node portion Ni.

The anode portion of the third diode Di3 is electrically connected to the cathode portion of the second diode Di2 to form a second node portion N2. The cathode portion of the third diode Di3 is electrically connected to the CMIS circuit 40 to form a third node portion N3. The cathode of the third diode Di3 outputs a boosted control voltage Vg to the gate of the first transistor Tr1.

The first to third capacitors C1 to C3 are respectively formed in a plurality of capacitive device regions 8d. Each of the first to third capacitors C1 to C3 has a first end and a second end. The first end of the first capacitor C1 is electrically connected to the first node portion Ni. The first end of the second capacitor C2 is electrically connected to the second node portion N2. The first end of the third capacitor C3 is electrically connected to the third node portion N3. The second end of the third capacitor C3 is electrically connected to the ground.

The boost control circuit 42 is formed in the boost control region 8e. The boost control circuit 42 is electrically connected to the second end of the first capacitor C1 and the second end of the second capacitor C2. The boost control circuit 42 generates a first pulse voltage Vp1 and outputs the first pulse voltage Vp1 to the second end of the first capacitor C1. The boost control circuit 42 generates a second pulse voltage Vp2 having a phase opposite to that of the first pulse voltage Vp1, and outputs the second pulse voltage Vp2 to the second end of the second capacitor C2.

For example, in the boost circuit 41, the non-boosted input voltage Vin may be 1 V or more and less than 3 V, and the boosted control voltage Vg may be 3 V or more and 10 V or less. For example, the control voltage Vg may be 4 V or more and 8 V or less. In order to avoid destruction of the first to third capacitors C1 to C3, the breakdown voltages of the first to third capacitors C1 to C3 can be adjusted to be equal to or higher than the control voltage Vg.

For example, the breakdown voltages of the first to third capacitors C1 to C3 can be increased by enlarging the plan-view area of each capacitive device region 8d. However, in this case, the plan-view area of the transistor region 6 is reduced and/or the size of the chip 2 is increased. Therefore, the first to third capacitors C1 to C3 are required to have a high breakdown voltage within a limited plan-view area. The specific configuration of the capacitor C (first to third capacitors C1 to C3) will be described later.

The current monitor circuit 25 generates a monitor current for monitoring the output current Io of the output transistor 20 and outputs the monitor current to other circuits. For example, the monitor circuit may include a transistor having the same configuration as the output transistor 20, and may be configured to be on/off controlled together with the output transistor 20 to generate a monitor current linked to the output current Io. Of course, the current monitor circuit 25 may be configured to generate a monitor current linked to one or more system currents Is.

The overcurrent protection circuit 26 generates an electrical signal for controlling the gate control circuit 24 based on the monitor current from the current monitor circuit 25 and controls the on/off of the output transistor 20 in cooperation with the gate control circuit 24. For example, the overcurrent protection circuit 26 may be configured to, when the monitor current is equal to or higher than a predetermined threshold value, determine that the output transistor 20 is in an overcurrent state, and turn off some or all of the output transistors 20 (the plurality of system transistors 21) in cooperation with the gate control circuit 24. In addition, the overcurrent protection circuit 26 may be configured to cooperate with the gate control circuit 24 to shift the output transistor 20 to a normal operation when the monitor current becomes less than the predetermined threshold value.

The overheat protection circuit 27 includes a first temperature sensing device (e.g., a temperature sensing diode) that detects the temperature of the transistor region 6 and a second temperature sensing device (e.g., a temperature sensing diode) that detects the temperature of control region 7. The overheat protection circuit 27 generates an electrical signal for controlling the gate control circuit 24 based on the first temperature detection signal from the first temperature sensing device and the second temperature detection signal from the second temperature sensing device, and controls the on/off of the output transistor 20 in cooperation with the gate control circuit 24.

For example, the overheat protection circuit 27 may be configured to, when the difference value between the first temperature detection signal and the second temperature detection signal is equal to or larger than a predetermined threshold value, determine that the transistor region 6 is in an overheated state, and turn off some or all of the output transistors 20 (the plurality of system transistors 21) in cooperation with the gate control circuit 24. Moreover, the overheat protection circuit 27 may be configured to cooperate with the gate control circuit 24 to shift the output transistor 20 to a normal operation when the difference value becomes less than the predetermined threshold value.

The low-voltage malfunction avoidance circuit 28 is configured to prevent various functional circuits in the control circuit 23 from malfunctioning when the activation voltage for activating the control circuit 23 is less than a predetermined value. For example, the low-voltage malfunction avoidance circuit 28 may be configured to activate the control circuit 23 when the activation voltage is equal to or higher than the predetermined threshold voltage, and stop the control circuit 23 when the activation voltage is less than the predetermined threshold voltage. The threshold voltage may have hysteresis characteristics.

The open load detection circuit 29 determines an electrical connection state of the inductive load L. For example, the open load detection circuit 29 may be configured to monitor the voltage across the terminals of the output transistor 20 and, when the voltage across the terminals is equal to or larger than a predetermined threshold value, determine that the inductive load L is in an open state. For example, the open load detection circuit 29 may be configured to, when the monitor current becomes equal to or smaller than a predetermined threshold value, determine that the inductive load L is in an open state.

The active clamp circuit 30 is electrically connected to the main drain and at least one main gate of the output transistor 20 (e.g., the system gate of the first system transistor 21A). The active clamp circuit 30 includes a Zener diode and a pn junction diode reverse-biased in series with the Zener diode. The pn junction diode is a backflow prevention diode that prevents backflow from the output transistor 20.

The active clamp circuit 30 is configured to cooperate with the gate control circuit 24 to turn on some or all of the output transistors 20 when a reverse voltage caused by the inductive load L is applied to the output transistor 20. Specifically, the output transistor 20 is controlled in multiple types of operation modes including a normal operation, a first off operation, an active clamp operation, and a second off operation.

In the normal operation, both the first system transistor 21A and the second system transistor 21B are controlled to be turned on at the same time. As a result, the channel utilization rate of the output transistor 20 increases and the on-resistance decreases. In the first off operation, both the first system transistor 21A and the second system transistor 21B are simultaneously controlled from the on state to the off state. As a result, the reverse voltage caused by the inductive load L is applied to both the first system transistor 21A and the second system transistor 21B.

The active clamp operation is an operation in which the output transistor 20 is allowed to absorb (consume) the energy accumulated in the inductive load L. The active clamp operation is executed when the reverse voltage caused by the inductive load L is equal to or higher than a predetermined threshold voltage. In the active clamp operation, the first system transistor 21A is controlled from the off state to the on state, and at the same time, the second system transistor 21B is controlled (maintained) in the off state.

The channel utilization rate of the output transistor 20 during the active clamp operation is less than the channel utilization rate of the output transistor 20 during the normal operation. The on-resistance of the output transistor 20 during the active clamp operation is greater than the on-resistance of the output transistor 20 during the normal operation. This suppresses a sudden rise of the temperature of the output transistor 20 during the active clamp operation, and improves the active clamp resistance.

The second off operation is performed when the reverse voltage becomes less than a predetermined threshold voltage. In the second off operation, the first system transistor 21A is controlled from the on state to the off state, and at the same time, the second system transistor 21B is controlled (maintained) in the off state. Thus, the reverse voltage (energy) of the inductive load L is absorbed by some of the output transistors 20 (here, the first system transistor 21A). Of course, during the active clamp operation, the first system transistor 21A may be controlled (maintained) in the off state, and the second system transistor 21B may be controlled in the on state.

The power source reverse connection protection circuit 31 is configured to detect a reverse voltage when the power source is connected in reverse, and protect the control circuit 23 and the output transistor 20 from the reverse voltage (reverse current). The logic circuit 32 is configured to generate electrical signals that are supplied to various circuits within the control circuit 23.

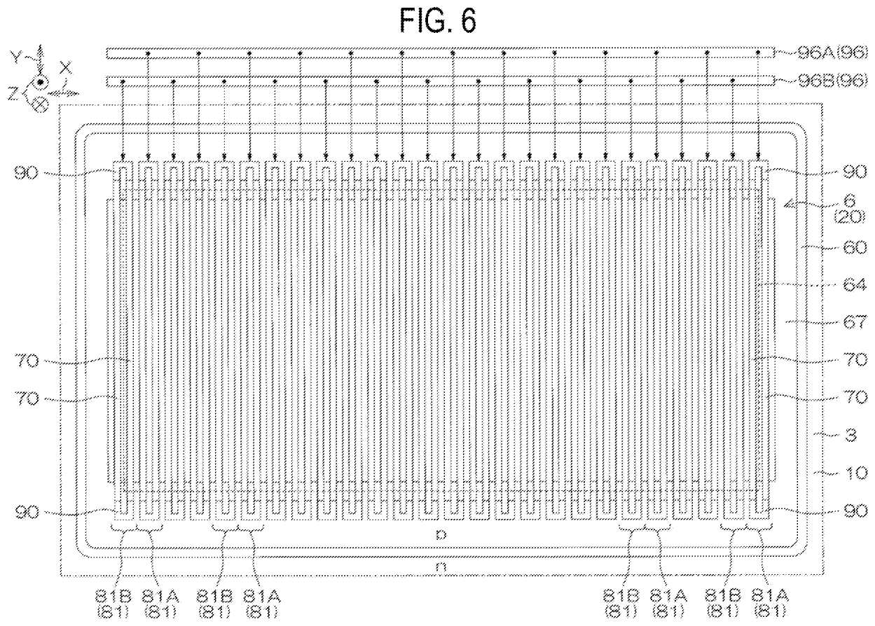

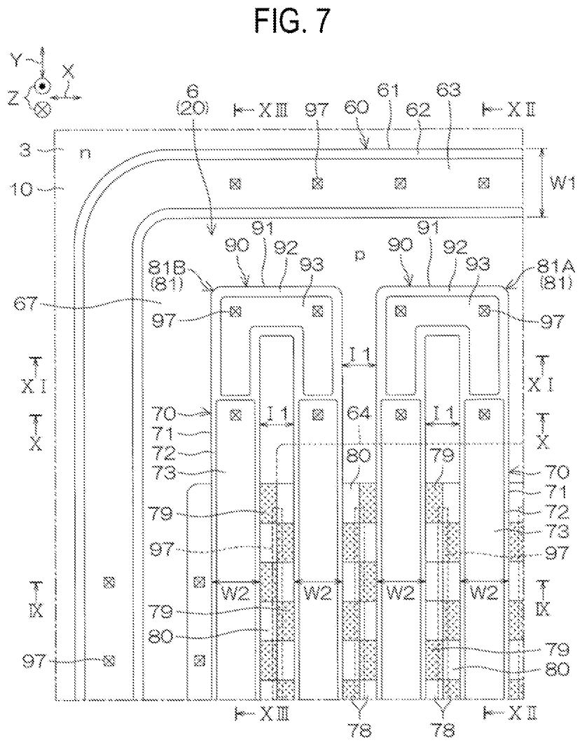

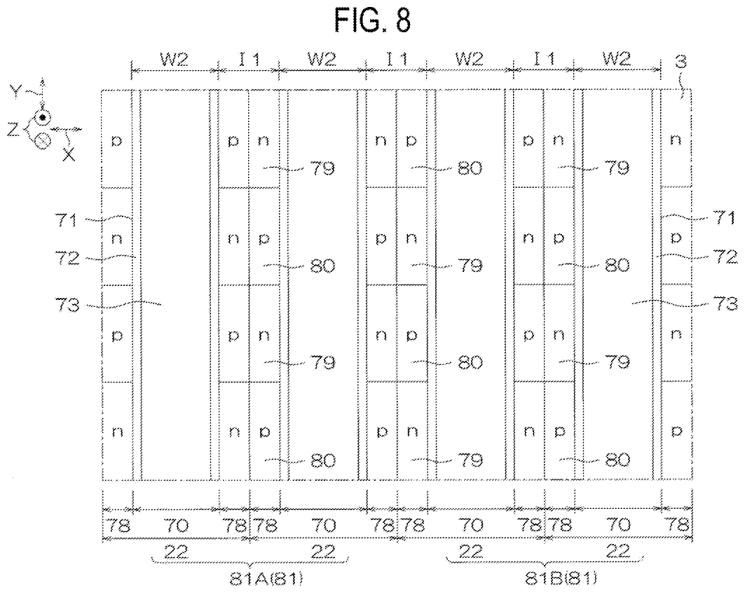

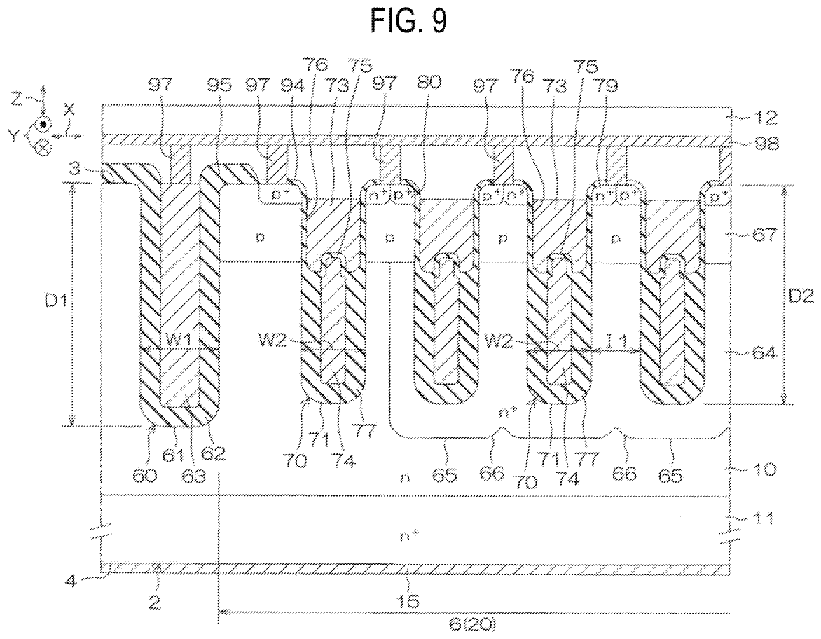

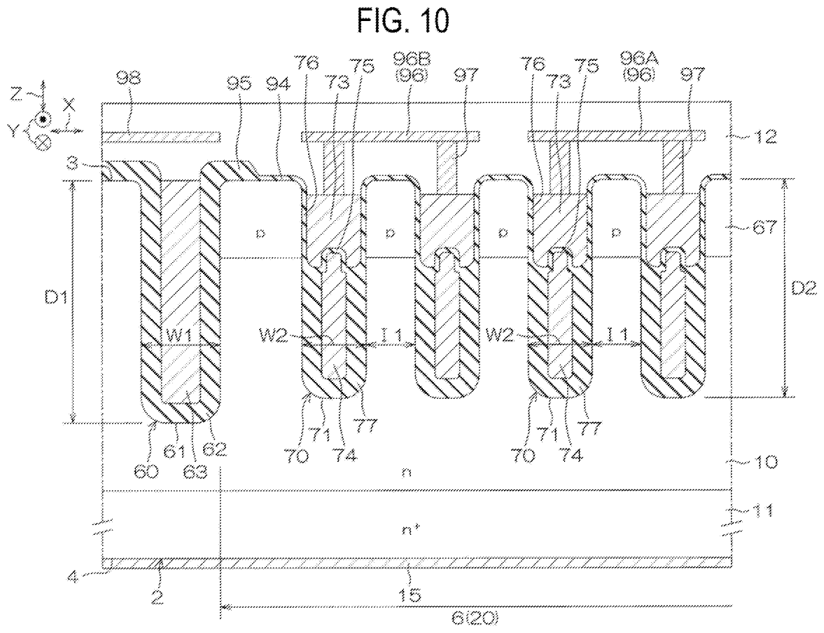

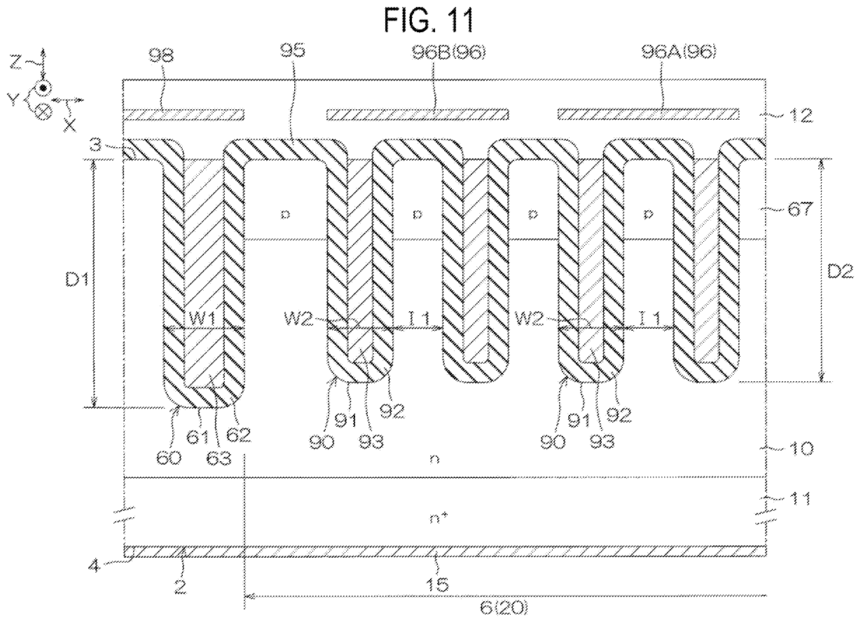

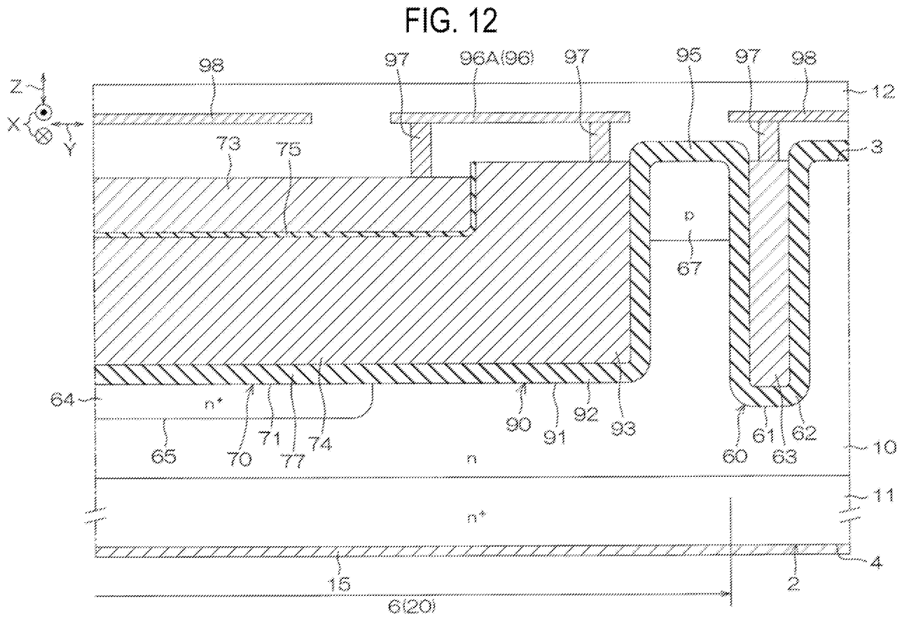

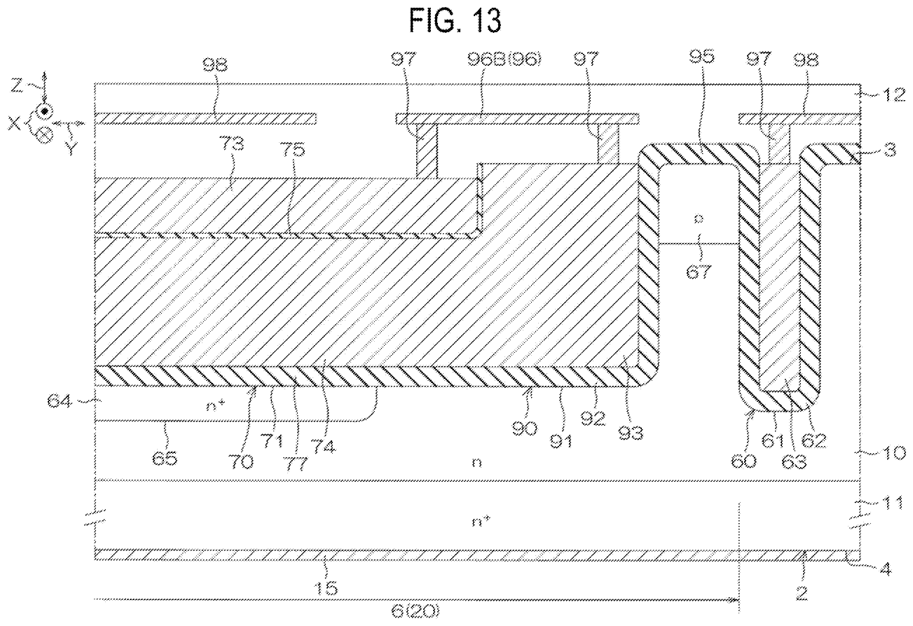

The configuration of the transistor region 6 will be described below with reference to FIGS. 6 to 13. FIG. 6 is a plan view showing the transistor region 6 shown in FIG. 1. FIG. 7 is an enlarged plan view showing a main part of the transistor region 6 shown in FIG. 6. FIG. 8 is an enlarged plan view showing another main part of the transistor region 6 shown in FIG. 6. FIG. 9 is a cross-sectional view taken along line IX-IX in FIG. 7. FIG. 10 is a cross-sectional view taken along line X-X in FIG. 7. FIG. 11 is a cross-sectional view taken along line XI-XI in FIG. 7. FIG. 12 is a cross-sectional view taken along line XII-XII in FIG. 7. FIG. 13 is a cross-sectional view taken along line XIII-XIII in FIG. 7.

The semiconductor device 1 includes a first trench isolation structure 60 formed in the first main surface 3 so as to define the transistor region 6. The first trench isolation structure 60 may be referred to as a “first region isolation structure.” The first trench isolation structure 60 electrically isolates the transistor region 6 from the control region 7 within the chip 2. A source electric potential is applied to the first trench isolation structure 60.

The first trench isolation structure 60 is formed in an annular shape surrounding the transistor region 6 in a plan view. In this embodiment, the first trench isolation structure 60 is formed in a polygonal ring shape (a quadrangular ring shape, in this embodiment) having four sides parallel to the peripheral edges of the first main surface 3 in a plan view. The first trench isolation structure 60 is formed to be spaced apart from the bottom portion of the first semiconductor region 10 toward the first main surface 3 to face the second semiconductor region 11 with a portion of the first semiconductor region 10 disposed between the first trench isolation structure 60 and the second semiconductor region 11.

The first trench isolation structure 60 has a first width W1. The first width W1 is the width in a direction perpendicular to the extension direction of the first trench isolation structure 60. The first width W1 may be 0.4 μm or more and 2.5 μm or less. The first width W1 may have a value belonging to any one of ranges of 0.4 μm or more and 0.75 μm or less, 0.75 μm or more and 1 μm or less, 1 μm or more and 1.25 μm less, 1.25 μm or more and 1.5 μm or less, 1.5 μm or more and 1.75 μm or less, and 1.75 μm or more and 2 μm or less. The first width W1 may be 1.25 μm or more and 1.75 μm or less.

The first trench isolation structure 60 has a first depth D1. The first depth D1 may be 1 μm or more and 6 μm or less. The first depth D1 may have a value belonging to any one of ranges of 1 μm or more and 2 μm or less, 2 μm or more and 3 μm or less, 3 μm or more and 4 μm or less, 4 μm or more and 5 μm or less, and 5 μm or more and 6 μm or less. The first depth D1 may be 2.5 μm or more and 4.5 μm or less.

The first trench isolation structure 60 includes a first isolation trench 61, a first isolation insulating film 62, and a first isolation electrode 63. That is, the first trench isolation structure 60 has a single electrode structure including a single electrode (first isolation electrode 63) embedded in the first isolation trench 61 and disposed between portions of an insulator (first isolation insulating film 62).

The first isolation trench 61 is formed in the first main surface 3 and defines a wall surface of the first trench isolation structure 60. The first isolation insulating film 62 covers the wall surface of the first isolation trench 61. The first isolation insulating film 62 may include a silicon oxide film. The first isolation insulating film 62 may include a silicon oxide film made of an oxide of the chip 2, or may include a silicon oxide film formed by a CVD method. The first isolation electrode 63 is embedded in the first isolation trench 61 and disposed between portions of the first isolation insulating film 62. The first isolation electrode 63 may contain conductive polysilicon.

The semiconductor device 1 includes an output transistor 20 formed on the first main surface 3 in the transistor region 6. The following configuration is described as a component of the semiconductor device 1. However, the following configuration may be a component of the output transistor 20.

The semiconductor device 1 includes an n-type high-concentration region 64 formed in the surface layer portion of the first semiconductor region 10 in the transistor region 6. The high-concentration region 64 may be referred to as a “high-concentration drift region.” The high-concentration region 64 has an n-type impurity concentration higher than that of the first semiconductor region 10. The n-type impurity concentration of the high-concentration region 64 may be less than the n-type impurity concentration of the second semiconductor region 11. The n-type impurity concentration of the high-concentration region 64 may be 1×10¹⁶ cm⁻³ or more and 1×10¹⁹ cm⁻³ or less. The high-concentration region 64 may be regarded as the high-concentration portion of the first semiconductor region 10.

The high-concentration region 64 forms a concentration gradient in which the n-type impurity concentration increases from the bottom side of the first semiconductor region 10 toward the first main surface 3 within the first semiconductor region 10. That is, the first semiconductor region 10 of the transistor region 6 has a concentration gradient formed by the high-concentration region 64 such that the n-type impurity concentration increases from the bottom side toward the first main surface 3.

The high-concentration region 64 is formed in the inner portion of the transistor region 6 so as to be spaced apart from the first trench isolation structure 60. The high-concentration region 64 is surrounded by the first semiconductor region 10 in the transistor region 6 and is not contiguous to the first trench isolation structure 60. The high-concentration region 64 locally increases the n-type impurity concentration of the first semiconductor region 10 in the transistor region 6.

The high-concentration region 64 is formed to be spaced apart from the bottom portion of the first semiconductor region 10 toward the first main surface 3 so as to face the second semiconductor region 11 with a portion of the first semiconductor region 10 disposed between the high-concentration region 64 and the second semiconductor region 11. The high-concentration region 64 has a bottom portion positioned closer to the bottom portion of the first semiconductor region 10 than the bottom wall of the first trench isolation structure 60. The bottom portion of the high-concentration region 64 meanders toward one side and the other side in the thickness direction in a cross-sectional view.

Specifically, the bottom portion of the high-concentration region 64 has a plurality of bulging portions 65 and a plurality of recessed portions 66 in a cross-sectional view. The bulging portions 65 are portions that bulge in an arc shape toward the bottom portion of the first semiconductor region 10. The bulging portions 65 are formed continuously in the first direction X in a plan view, and are respectively formed in a stripe shape extending in the second direction Y. Each bulging portion 65 is formed wider in the first direction X than the first trench isolation structure 60.

The recessed portions 66 are respectively formed in a stripe shape extending in the second direction Y in the regions between the bulging portions 65. The recessed portions 66 are portions where shallow portions of the bulging portions 65 are connected to each other, and are located on the first main surface 3 side with respect to deepest portions of the bulging portions 65. Of course, the high-concentration region 64 may have a flat bottom portion without meandering up and down in the thickness direction.

The high-concentration region 64 may be formed by increasing the concentration of the entire first semiconductor region 10 within the transistor region 6. With such a configuration, the on-resistance of the first semiconductor region 10 can be reduced by increasing the concentration of the first semiconductor region 10. However, in this case, it should be noted that the increase in carrier density in the first semiconductor region 10 may make electric field concentration more likely to occur, resulting in a decrease in breakdown voltage. Therefore, the high-concentration region 64 may be introduced into a part of the transistor region 6 in order to reduce the on-resistance while suppressing the decrease in breakdown voltage.

The semiconductor device 1 includes a p-type (second conductivity type) body region 67 formed in the surface layer portion of the first semiconductor region 10 in the transistor region 6. The body region 67 extends in a layer shape along the first main surface 3 throughout the transistor region 6 and is connected to the wall surface of the first trench isolation structure 60. That is, the body region 67 is not formed outside the first trench isolation structure 60 in this embodiment.

The body region 67 is formed shallower than the high-concentration region 64. Specifically, the body region 67 is formed shallower than the first trench isolation structure 60 and has a bottom portion located closer to the first main surface 3 than the bottom wall of the first trench isolation structure 60. The bottom portion of the body region 67 may be located closer to the first main surface 3 than the middle portion in the depth range of the first trench isolation structure 60.

The semiconductor device 1 includes a plurality of trench gate structures 70 formed in the first main surface 3 in the transistor region 6. The trench gate structures 70 are formed in the inner portion of the transistor region 6 so as to be spaced apart from the first trench isolation structure 60. The trench gate structures 70 are arranged at intervals in the first direction X and formed in a stripe shape extending in the second direction Y. That is, the trench gate structures 70 are arranged in a stripe shape extending in the second direction Y. The trench gate structures 70 extend across one end and the other end of the high-concentration region 64 in the longitudinal direction (second direction Y).

Each of the trench gate structures 70 has a first end on one side in the longitudinal direction (second direction Y) and a second end on the other side in the longitudinal direction (second direction Y). The first end is located in a region between one ends of the first trench isolation structure 60 and the high-concentration region 64 in a plan view. The second end is located in a region between the other ends of the first trench isolation structure 60 and the high-concentration region 64 in a plan view.

The trench gate structures 70 penetrate the body region 67 in a cross-sectional view and are located in the high-concentration region 64. The trench gate structures 70 are formed at intervals from the bottom portion of the high-concentration region 64 toward the first main surface 3 so as to face the first semiconductor region 10 with a portion of the high-concentration region 64 disposed between the trench gate structures 70 and the first semiconductor region 10.

The trench gate structures 70 are formed to be offset in the first direction X with respect to the recessed portions 66 so as to face the bulging portions 65 in the thickness direction. The trench gate structures 70 may face the deepest portions of the bulging portions 65. Such a configuration is obtained by introducing an n-type impurity into the chip 2 through the walls of gate trenches 71 after the step of forming the gate trenches 71.

The two trench gate structures 70 positioned on both sides in the first direction X may be formed in regions outside the high-concentration region 64. In other words, the outermost trench gate structure 70 may penetrate the body region 67 at a position spaced apart from the high-concentration region 64 toward the first trench isolation structure 60 and is located within the first semiconductor region 10. The outermost trench gate structure 70 is formed to be spaced apart from the bottom portion of the first semiconductor region 10 toward the first main surface 3 so as to face the second semiconductor region 11 with a portion of the first semiconductor region 10 disposed between the outermost trench gate structure 70 and the second semiconductor region 11.

The trench gate structures 70 have a second width W2. The second width W2 is the width in a direction perpendicular to the extension direction of the trench gate structure 70 (i.e., in the first direction X). The second width W2 may be substantially equal to the first width W1 of the first trench isolation structure 60. The second width W2 may be equal to or less than the first width W1. The second width W2 may be less than the first width W1.

The second width W2 may be 0.4 μm or more and 2 μm or less. The second width W2 may have a value belonging to any one of ranges of 0.4 μm or more and 0.75 μm or less, 0.75 μm or more and 1 μm or less, 1 μm or more and 1.25 μm or less, 1.25 μm or more and 1.5 μm or less, 1.5 μm or more and 1.75 μm or less, and 1.75 μm or more and 2 μm or less. The second width W2 may be 0.8 μm or more and 1.2 μm or less.

The trench gate structures 70 are arranged at first intervals I1 in the first direction X. The first interval I1 is also the mesa width (first mesa width) of a mesa portion (first mesa portion) defined in the region between the two trench gate structures 70 adjacent to each other. The first interval I1 may be equal to or less than the first width W1 of the first trench isolation structure 60. The first interval I1 may be equal to or less than the second width W2. The first interval I1 may be less than the second width W2.

The first interval I1 may be 0.4 μm or more and 0.8 μm or less. The first interval I1 may have a value belonging to any one of ranges of 0.4 μm or more and 0.5 μm or less, 0.5 μm or more and 0.6 μm or less, 0.6 μm or more and 0.7 μm or less, and 0.7 μm or more and 0.8 μm or less. The first interval I1 may be 0.5 μm or more and 0.7 μm or less.

The trench gate structure 70 has a second depth D2. The second depth D2 may be substantially equal to the first depth D1 of the first trench isolation structure 60. The second depth D2 may be equal to or less than the first depth D1. The second depth D2 may be less than the first depth D1.

The second depth D2 may be 1 μm or more and 6 μm or less. The second depth D2 may have a value belonging to any one of ranges of 1 μm or more and 2 μm or less, 2 μm or more and 3 μm or less, 3 μm or more and 4 μm or less, 4 μm or more and 5 μm or less, and 5 μm or more and 6 μm or less. The second depth D2 may be 2.5 μm or more and 4.5 μm or less.

An internal configuration of one trench gate structure 70 will be described below. The trench gate structure 70 includes a gate trench 71, a gate insulating film 72, a gate upper electrode 73, a gate lower electrode 74, and a gate intermediate insulating film 75. That is, the trench gate structure 70 includes a gate embedded electrode embedded in the gate trench 71 and disposed between portions of the gate insulating film. The gate embedded electrode has a multi-electrode structure including a plurality of electrodes (gate upper electrode 73 and gate lower electrode 74) vertically embedded in the gate trench 71.

The gate trench 71 is formed in the first main surface 3 to define a wall surface of the trench gate structure 70. The gate insulating film 72 covers the wall surface of the gate trench 71. The gate insulating film 72 includes a gate upper insulating film 76 and a gate lower insulating film 77. The gate upper insulating film 76 covers the opening-side wall surface of the gate trench 71 with respect to the bottom portion of the body region 67.

The gate upper insulating film 76 has a portion that crosses the boundary between the first semiconductor region 10 (high-concentration region 64) and the body region 67 and covers the first semiconductor region 10 (high-concentration region 64). In this case, the covering area of the gate upper insulating film 76 with respect to the body region 67 may be larger than the covering area of the gate upper insulating film 76 with respect to the first semiconductor region 10 (high-concentration region 64).

The gate upper insulating film 76 is thinner than the first isolation insulating film 62. The gate upper insulating film 76 is formed as a gate insulating film for channel control. The gate upper insulating film 76 may include a silicon oxide film. The gate upper insulating film 76 may include a silicon oxide film made of an oxide of the chip 2.

The gate upper insulating film 76 may have a thickness of 1 nm or more and 50 nm or less. The thickness of the gate upper insulating film 76 may have a value belonging to any one of ranges of 1 nm or more and 5 nm or less, 5 nm or more and 10 nm or less, 10 nm or more and 15 nm or less, 15 nm or more and 20 nm or less, 20 nm or more and 25 nm or less, 25 nm or more and 30 nm or less, 30 nm or more and 35 nm or less, 35 nm or more and 40 nm or less, 40 nm or more and 45 nm or less, and 45 nm or more and 50 nm or less.

The thickness of the gate upper insulating film 76 may be 5 nm or more and 15 nm or less. The thickness of the gate upper insulating film 76 may be 5 nm or more and 10 nm or less. The thickness of the gate upper insulating film 76 may be 10 nm or more and 15 nm or less.

The gate lower insulating film 77 covers the bottom-side wall surface of the gate trench 71 with respect to the bottom portion of the body region 67. The gate lower insulating film 77 covers the first semiconductor region 10 (high-concentration region 64). The covering area of the gate lower insulating film 77 with respect to the first semiconductor region 10 (high-concentration region 64) is larger than the covering area of the gate upper insulating film 76 with respect to the body region 67.

The gate lower insulating film 77 may have a portion that crosses the boundary between the first semiconductor region 10 (high-concentration region 64) and the body region 67 and covers the bottom portion of the body region 67. The gate lower insulating film 77 is thicker than the gate upper insulating film 76. The thickness of the gate lower insulating film 77 may be 10 to 50 times the thickness of the gate upper insulating film 76.

The thickness of the gate lower insulating film 77 may be substantially equal to the thickness of the first isolation insulating film 62. The gate lower insulating film 77 may contain a silicon oxide film. The gate lower insulating film 77 may include a silicon oxide film made of an oxide of the chip 2, or may include a silicon oxide film formed by a CVD method.

The gate lower insulating film 77 may have a thickness of 100 nm or more and 500 nm or less. The thickness of the gate lower insulating film 77 may have a value belonging to any one of ranges of 100 nm or more and 150 nm or less, 150 nm or more and 200 nm or less, 200 nm or more and 250 nm or less, 250 nm or more and 300 nm or less, 300 nm or more and 350 nm or less, 350 nm or more and 400 nm or less, 400 nm or more and 450 nm or less, and 450 nm or more and 500 nm or less. The thickness of the gate lower insulating film 77 may be 200 nm or more and 250 nm or less.

The gate upper electrode 73 is embedded in the gate trench 71 at the opening side and disposed between portions of the gate insulating film 72. Specifically, the gate upper electrode 73 is embedded in the gate trench 71 at the opening side and disposed between portions of the gate upper insulating film 76, and faces the body region 67 and the high-concentration region 64 with the gate upper insulating film 76 disposed between the gate upper electrode 73 and the body region 67, and between the gate upper electrode 73 and the high-concentration region 64.

In other words, the gate upper electrode 73 is embedded in the gate trench 71 at the opening side with respect to the bottom portion of the body region 67, and controls inversion and non-inversion of the channel in the body region 67. The facing area of the gate upper electrode 73 with respect to the body region 67 is larger than the facing area of the gate upper electrode 73 with respect to the first semiconductor region 10 (high-concentration region 64). The gate upper electrode 73 may contain conductive polysilicon.

The gate lower electrode 74 is embedded in the gate trench 71 at the bottom wall side and disposed between portions of the gate insulating film 72. Specifically, the gate lower electrode 74 is embedded in the gate trench 71 at the bottom wall side, disposed between portions of the gate lower insulating film 77, and faces the high-concentration region 64 with the gate lower insulating film 77 disposed between the gate lower electrode 74 and the high-concentration region 64. That is, the gate lower electrode 74 is embedded in the gate trench 71 at the bottom wall side with respect to the bottom portion of the body region 67.

The facing area of the gate lower electrode 74 with respect to the first semiconductor region 10 (high-concentration region 64) is larger than the facing area of the gate upper electrode 73 with respect to the body region 67. The gate lower electrode 74 of the outermost trench gate structure 70 faces the first semiconductor region 10 with the gate lower insulating film 77 disposed between the outermost trench gate structure 70 and the first semiconductor region 10.

The gate lower electrode 74 extends like a wall along the depth direction of the gate trench 71 (the thickness direction of the chip 2). The gate lower electrode 74 has an upper end portion protruding from the gate lower insulating film 77 toward the gate upper electrode 73 so as to engage with the bottom portion of the gate upper electrode 73. The upper end portion of the gate lower electrode 74 faces the gate upper insulating film 76 across the lower end portion of the gate upper electrode 73 in the lateral direction along the first main surface 3. The gate lower electrode 74 may contain conductive polysilicon.

The gate intermediate insulating film 75 is disposed between the gate upper electrode 73 and the gate lower electrode 74 to electrically insulate the gate upper electrode 73 and the gate lower electrode 74 in the gate trench 71. The gate intermediate insulating film 75 is connected to the gate upper insulating film 76 and the gate lower insulating film 77. The gate intermediate insulating film 75 is thinner than the gate lower insulating film 77. The gate intermediate insulating film 75 may include a silicon oxide film. The gate intermediate insulating film 75 may include a silicon oxide film made of an oxide of the gate lower electrode 74.

The semiconductor device 1 includes a plurality of channel cells 78 formed on both sides of each trench gate structure 70 as targets to be controlled by each trench gate structure 70. In this embodiment, the two channel cells 78 arranged on both sides of one trench gate structure 70 are controlled by the one trench gate structure 70 and are not controlled by other trench gate structures 70.

The channel cells 78 are formed in regions along the inner portion of the trench gate structure 70 at intervals from both ends of the trench gate structure 70 in the longitudinal direction (second direction Y). The channel cells 78 expose the body region 67 from the regions of the first main surface 3 sandwiched between both end portions of the plurality of trench gate structures 70.

The channel cells 78 face the high-concentration region 64 with a portion of the body region 67 disposed between the channel cells 78 and the high-concentration region 64 in the thickness direction. The channel cells 78 may be formed in the inner portion of the high-concentration region 64 rather than the peripheral edge of the high-concentration region 64 in a plan view.

Each channel cell 78 includes a plurality of n-type source regions 79 and a plurality of p-type high-concentration body regions 80. In FIG. 7, for the sake of clarity, the source region 79 is hatched. The high-concentration body regions 80 may also be referred to as “contact regions” or “back gate regions.”

Each source region 79 has a higher n-type impurity concentration than the first semiconductor region 10. Each source region 79 may have a higher n-type impurity concentration than the high-concentration region 64. The n-type impurity concentration of each source region 79 may be 1×10¹⁸ cm⁻³ or more and 1×10²¹ cm⁻³ or less.

The source regions 79 are arranged at intervals along each trench gate structure 70. The source regions 79 are formed at intervals from the bottom portion of the body region 67 toward the first main surface 3 to face the gate upper electrode 73 with the gate insulating film 72 (gate upper insulating film 76) disposed between the source regions 79 and the gate upper electrode 73.

Each high-concentration body region 80 has a higher p-type impurity concentration than the body region 67. The p-type impurity concentration of each high-concentration body region 80 may be 1×10¹⁸ cm⁻³ or more and 1×10²¹ cm⁻³ or less. The high-concentration body regions 80 are alternately arranged with the source regions 79 along each trench gate structure 70. The high-concentration body regions 80 are formed at intervals from the bottom portion of the body region 67 toward the first main surface 3 to face the gate upper electrode 73 with the gate insulating film 72 (gate upper insulating film 76) disposed between the high-concentration body regions 80 and the gate upper electrode 73.

Regarding the two channel cells 78 formed on both sides of one trench gate structure 70, the source regions 79 in one channel cell 78 face the source regions 79 in the other channel cell 78 with the trench gate structure 70 disposed between them. In addition, the high-concentration body regions 80 in one channel cell 78 face the high-concentration body regions 80 in the other channel cell 78 with the trench gate structure 70 disposed between them.

Of course, the source regions 79 in one channel cell 78 may face the high-concentration body regions 80 in the other channel cell 78 with the trench gate structure 70 disposed between the source regions 79 and the high-concentration body regions 80. Further, the high-concentration body regions 80 in one channel cell 78 may face the source regions 79 in the other channel cell 78 with the trench gate structure 70 disposed between the high-concentration body regions 80 and the source regions 79.

Regarding the two channel cells 78 disposed between two trench gate structures 70, the source regions 79 in one channel cell 78 are connected to the high-concentration body regions 80 in the other channel cell 78 in the first direction X. In addition, the high-concentration body regions 80 in one channel cell 78 are connected to the source regions 79 in the other channel cell 78 in the first direction X.

Of course, the source regions 79 in one channel cell 78 may be connected to the source regions 79 in the other channel cell 78 in the first direction X. Further, the high-concentration body regions 80 in one channel cell 78 may be connected to the high-concentration body regions 80 in the other channel cell 78 in the first direction X.

Of the two channel cells 78 formed on both sides of the outermost trench gate structure 70, the channel cell 78 located on the inner side faces the first semiconductor region 10 with a portion of the body region 67 disposed between the channel cell 78 and the first semiconductor region 10 in the thickness direction. On the other hand, the channel cell 78 located on the outer side does not include the source region 79 but includes only the high-concentration body region 80. This suppresses formation of a current path in the region between the first trench isolation structure 60 and the outermost trench gate structure 70.

The output transistor 20 includes a plurality of unit transistors 22. Each unit transistor 22 includes one trench gate structure 70 and two channel cells 78 formed on both sides of the one trench gate structure 70. Regarding each unit transistor 22, one trench gate structure 70 constitutes a unit gate, the source regions 79 (two channel cells 78) constitute a unit source, and the second semiconductor region 11 (first semiconductor region 10 and high-concentration region 64) constitutes a unit drain.

The output transistor 20 includes a first system transistor 21A and a second system transistor 21B. The first system transistor 21A includes a plurality of unit transistors 22 systematized (grouped) as individual control targets from the unit transistors 22. The second system transistor 21B includes a plurality of unit transistors 22 systematized (grouped) as individual control targets from the unit transistors 22 other than the first system transistor 21A.

In this embodiment, the output transistor 20 includes a plurality of block regions 81 provided in the transistor region 6. The block regions 81 include a plurality of first block regions 81A and a plurality of second block regions 81B. The first block regions 81A are regions in which one or a plurality of (a plurality of, in this embodiment) unit transistors 22 for the first system transistor 21A is arranged. The second block regions 81B are regions in which one or a plurality of (a plurality of, in this embodiment) unit transistors 22 for the second system transistor 21B is arranged.

The first block regions 81A are arranged at intervals in the first direction X. The number of unit transistors 22 in each first block region 81A is arbitrary. In this embodiment, two unit transistors 22 are arranged in each first block region 81A. As the number of unit transistors 22 in each first block region 81A increases, the amount of heat generated in each first block region 81A increases. Therefore, the number of unit transistors 22 in each first block region 81A may be two or more and five or less.

The second block regions 81B are alternately arranged with the first block regions 81A along the first direction X so as to sandwich one first block region 81A. As a result, the heat generation locations caused by the plurality of first block regions 81A can be thinned out by the second block regions 81B, and at the same time, the heat generation locations caused by the second block regions 81B can be thinned out by the first block regions 81A.

The number of unit transistors 22 in each second block region 81B is arbitrary. In this embodiment, two unit transistors 22 are arranged in each second block region 81B. As the number of unit transistors 22 in each second block region 81B increases, the amount of heat generated in each second block region 81B increases.

Therefore, the number of unit transistors 22 in each second block region 81B may be two or more and five or less. Considering the in-plane variations in temperature in the transistor region 6, the number of unit transistors 22 in the second block region 81B may be the same as the number of unit transistors 22 in the first block region 81A.

The semiconductor device 1 includes a pair of first trench connection structures 90 connecting both end portions of a plurality of (two, in this embodiment) trench gate structures 70 to be systematized (grouped) in each block region 81. That is, the first trench connection structures 90 connect both end portions of a plurality of trench gate structures 70 to be systematized as system transistors 21.

The first trench connection structure 90 on one side connects the first end portions of a plurality of (two, in this embodiment) corresponding trench gate structures 70 in an arch shape in a plan view. The first trench connection structure 90 on the other side connects the second end portions of a plurality of (two, in this embodiment) corresponding trench gate structures 70 in an arch shape in a plan view.

Specifically, the first trench connection structure 90 on one side has a first portion extending in the first direction X and a plurality of (two, in this embodiment) second portions extending in the second direction Y. The first portion faces the first end portions of the plurality of trench gate structures 70 in a plan view. The second portions extend from the first portion toward the plurality of first end portions so as to be connected to the first end portions.

The first trench connection structure 90 on the other side has a first portion extending in the first direction X and a plurality of (two, in this embodiment) second portions extending in the second direction Y. The first portion faces the second end portions of the plurality of trench gate structures 70 in a plan view. The second portions extend from the first portion toward a plurality of second end portions so as to be connected to the second end portions. The first trench connection structures 90 constitute a plurality of trench gate structures 70 and one annular or ladder-like trench structure in each block region 81.

The first trench connection structures 90 are formed in the region between the first trench isolation structure 60 and the high-concentration region 64 so as to be spaced apart from the first trench isolation structure 60 and the high-concentration region 64. The first trench connection structures 90 are formed so as to be spaced apart from the bottom portion of the first semiconductor region 10 toward the first main surface 3, and face the second semiconductor region 11 with a portion of the first semiconductor region 10 disposed between the first trench connection structures 90 and the second semiconductor region 11.

The first trench connection structures 90 may be formed at a width and depth substantially equal to those of the trench gate structures 70. Of course, the first and second portions of the first trench connection structure 90 may have different widths. For example, the second portion of first trench connection structure 90 may be formed narrower than the first portion of the first trench connection structure 90.

In this case, the first portion may have a width substantially equal to the width of the first trench isolation structure 60, and the second portion may have a width substantially equal to the width of the trench gate structure 70. Further, in this case, the first portion may have a depth substantially equal to the depth of the first trench isolation structure 60, and the second portion may have a depth substantially equal to the depth of the trench gate structure 70.

The first trench connection structure 90 on the other side has the same structure as the first trench connection structure 90 on one side except that it is connected to the second end portion of the trench gate structure 70. Hereinafter, the configuration of the first trench connection structure 90 on one side will be described, and the description of the configuration of the first trench connection structure 90 on the other side will be omitted.

The first trench connection structure 90 includes a first connection trench 91, a first connection insulating film 92, and a first connection electrode 93. The first connection trench 91 is formed in the first main surface 3 to define a wall surface of the first trench connection structure 90. The first connection trench 91 is connected to the gate trenches 71.

The first connection insulating film 92 covers the wall surface of the first connection trench 91. The first connection insulating film 92 is connected to the gate upper insulating film 76, the gate lower insulating film 77, and the gate intermediate insulating film 75 at the communication portion between the first connection trench 91 and the gate trench 71. The first connection insulating film 92 is thicker than the gate upper insulating film 76. The thickness of the first connection insulating film 92 may be substantially equal to the thickness of the gate lower insulating film 77. The first connection insulating film 92 may include a silicon oxide film. The first connection insulating film 92 may include a silicon oxide film made of an oxide of the chip 2, or may include a silicon oxide film formed by a CVD method.

The first connection electrode 93 is embedded in the first connection trench 91 and disposed between portions of the first connection insulating film 92, faces the first semiconductor region 10 with the first connection insulating film 92 disposed between the first connection electrode 93 and the first semiconductor region 10, and faces the body region 67 with the first connection insulating film 92 disposed between the first connection electrode 93 and the body region 67. The first connection electrode 93 is connected to the gate lower electrode 74 at the communication portion between the first connection trench 91 and the gate trench 71, and is electrically insulated from the gate upper electrode 73 by the gate intermediate insulating film 75. The first connection electrode 93 is composed of a lead portion in which the gate lower electrode 74 is led out from the inside of the gate trench 71 into the first connection trench 91. The first connection electrode 93 may contain conductive polysilicon.

The semiconductor device 1 includes a first main surface insulating film 94 that selectively covers the first main surface 3 in the transistor region 6. The first main surface insulating film 94 is connected to the gate insulating film 72 (gate upper insulating film 76) and the first connection insulating film 92, and exposes the first isolation electrode 63, the gate upper electrode 73, and the first connection electrode 93.

The first main surface insulating film 94 is thinner than the first isolation insulating film 62. The first main surface insulating film 94 is thinner than the gate upper insulating film 77. The first main surface insulating film 94 is thinner than the first connection insulating film 92. The first main surface insulating film 94 may have a thickness substantially equal to that of the gate upper insulating film 76. The first main surface insulating film 94 may include a silicon oxide film. The first main surface insulating film 94 may include a silicon oxide film made of an oxide of the chip 2.

The semiconductor device 1 includes a first field insulating film 95 that selectively covers the first main surface 3 inside and outside the transistor region 6. The first field insulating film 95 is thicker than first main surface insulating film 94. The first field insulating film 95 is thicker than the gate upper insulating film 76. The first field insulating film 95 may have a thickness substantially equal to that of the first isolation insulating film 62. The first field insulating film 95 may include a silicon oxide film. The first field insulating film 95 may include a silicon oxide film made of an oxide of the chip 2, or may include a silicon oxide film formed by a CVD method.

The first field insulating film 95 covers the first main surface 3 along the inner wall of the first trench isolation structure 60 in the transistor region 6 and is connected to the first isolation insulating film 62, the first connection insulating film 92, and the first main surface insulating film 94. The first field insulating film 95 covers the first main surface 3 along the outer wall of the first trench isolation structure 60 outside the transistor region 6 and is connected to the first isolation insulating film 62.

The interlayer insulating layer 12 described above covers the first trench isolation structure 60, the trench gate structure 70, the first trench connection structure 90, the first main surface insulating film 94, and the first field insulating film 95 in the transistor region 6.

The semiconductor device 1 includes a plurality of gate wirings 96 arranged in the interlayer insulating layer 12. The gate wirings 96 are routed to the transistor region 6 and the control region 7. The gate wirings 96 are electrically connected to the output transistor 20 in the transistor region 6, and electrically connected to the control circuit 23 (gate control circuit 24) in the control region 7. The gate wirings 96 individually transmit a plurality of gate signals generated by the control circuit 23 (gate control circuit 24) to the output transistor 20.

The gate wirings 96 include a first system gate wiring 96A and a second system gate wiring 96B. The first system gate wiring 96A individually transmits a gate signal to the first system transistors 21A. The first system gate wiring 96A is electrically connected to the trench gate structures 70 for the first system transistor 21A through a plurality of via electrodes 97 arranged in the interlayer insulating layer 12. Specifically, the first system gate wiring 96A is electrically connected to the corresponding gate upper electrodes 73 and the first connection electrodes 93 through the via electrodes 97.

That is, the gate upper electrode 73 and the gate lower electrode 74 for the first system transistor 21A are simultaneously on/off controlled by the same gate signal. This suppresses the voltage drop between the gate upper electrode 73 and the gate lower electrode 74, and suppresses unwanted electric field concentration. As a result, a decrease in breakdown voltage due to the electric field concentration is suppressed.

The second system gate wiring 96B is electrically independent from the first system gate wiring 96A and individually transmits gate signals to the second system transistors 21B. The second system gate wiring 96B is electrically connected to the trench gate structures 70 for the second system transistor 21B through a plurality of via electrodes 97 arranged in the interlayer insulating layer 12. Specifically, the second system gate wiring 96B is electrically connected to the corresponding gate upper electrodes 73 and the corresponding first connection electrodes 93 through the via electrodes 97.

That is, the gate upper electrode 73 and the gate lower electrode 74 for the second system transistor 21B are simultaneously on/off controlled by the same gate signal. This suppresses the voltage drop between the gate upper electrode 73 and the gate lower electrode 74, and suppresses unwanted electric field concentration. As a result, a decrease in breakdown voltage due to the electric field concentration is suppressed.

The semiconductor device 1 includes a source wiring 98 arranged in interlayer insulating layer 12. The source wiring 98 is electrically connected to the source terminal 13, the first trench isolation structure 60, and the channel cells 78. Specifically, the source wiring 98 is electrically connected to the first trench isolation structure 60 and the channel cells 78 through a plurality of via electrodes 97 arranged in the interlayer insulating layer 12.

The via electrode 97 for each channel cell 78 is arranged so as to straddle two adjacent channel cells 78 and is formed in a stripe shape extending along each channel cell 78 in a plan view. Thus, the source terminal 13 is electrically connected to the system sources of all the system transistors 21 (the unit sources of the unit transistors 22).

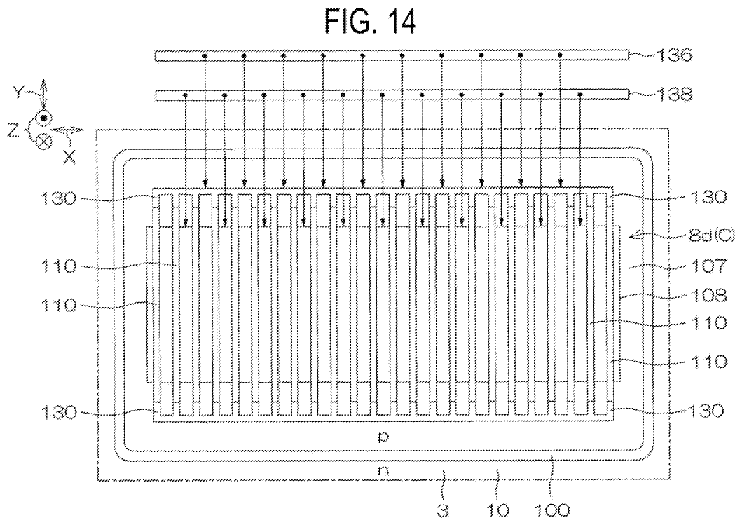

The configuration of one capacitive device region 8d (capacitor C) will be described below with reference to FIGS. 14 to 21. The capacitive device regions 8d (capacitors C) have the same configuration except that the electrical connection form, arrangement location, plan-view area (capacitance value), and the like are different (see also FIGS. 1 to 5). Therefore, the following description applies to each capacitive device region 8d (capacitor C).

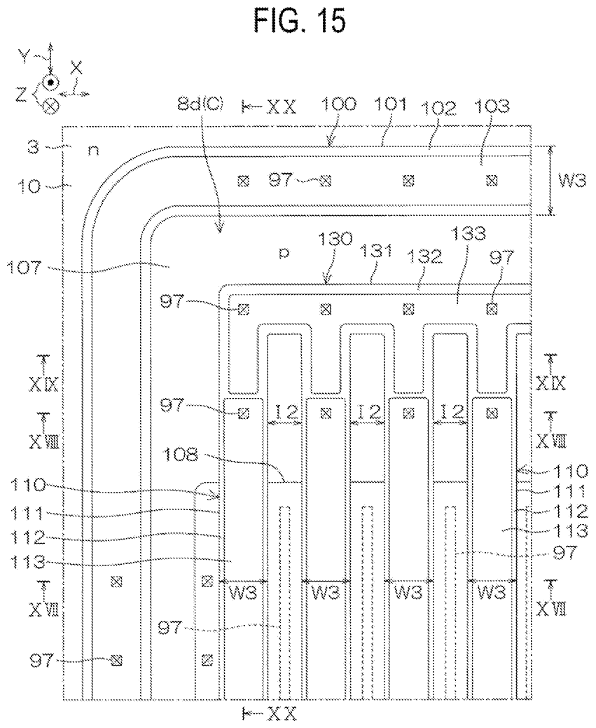

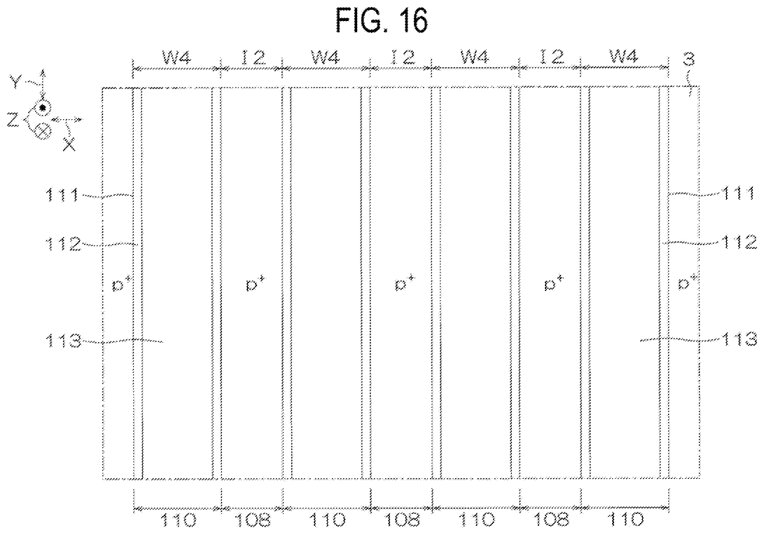

FIG. 14 is a plan view showing the capacitive device region 8d shown in FIG. 1. FIG. 15 is an enlarged plan view showing a main part of the capacitive device region 8d shown in FIG. 14. FIG. 16 is an enlarged plan view showing another main part of the capacitive device region 8d shown in FIG. 14.

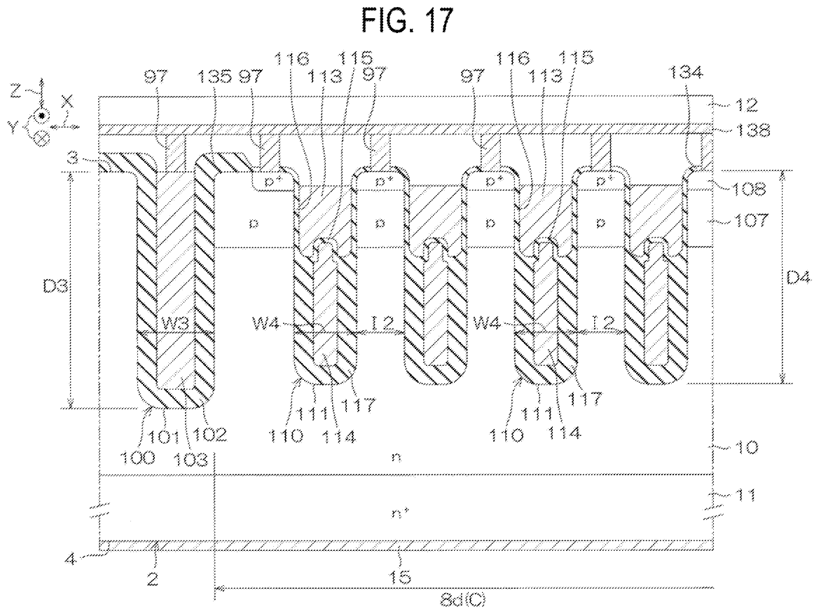

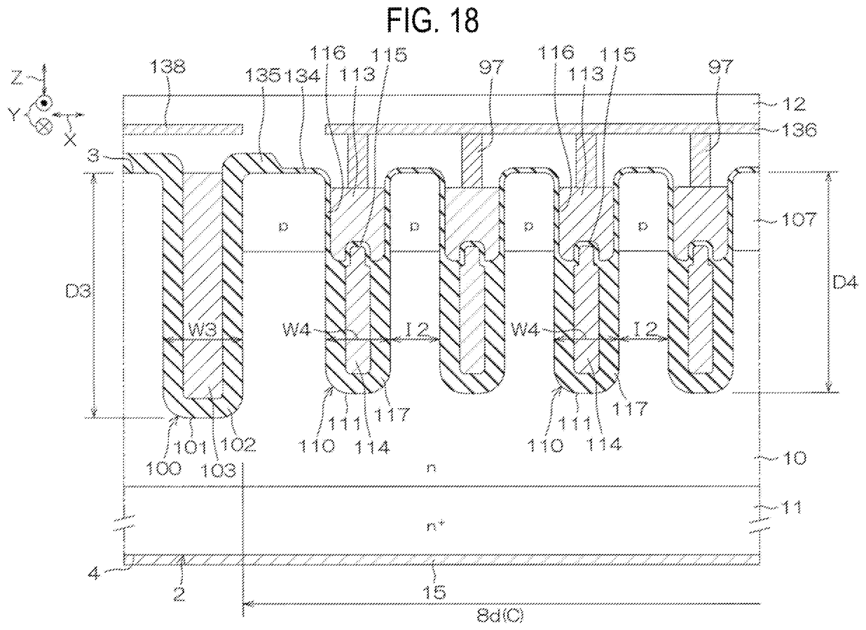

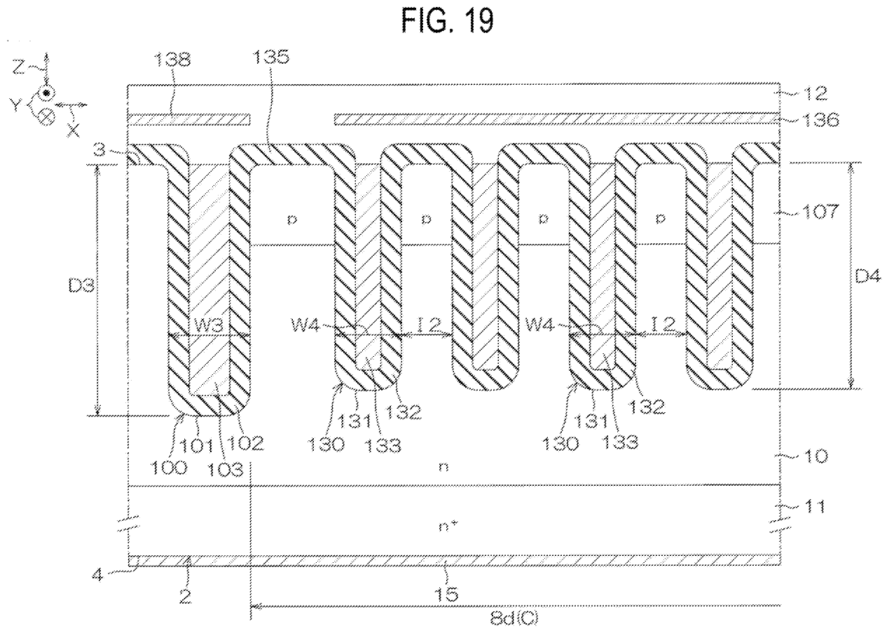

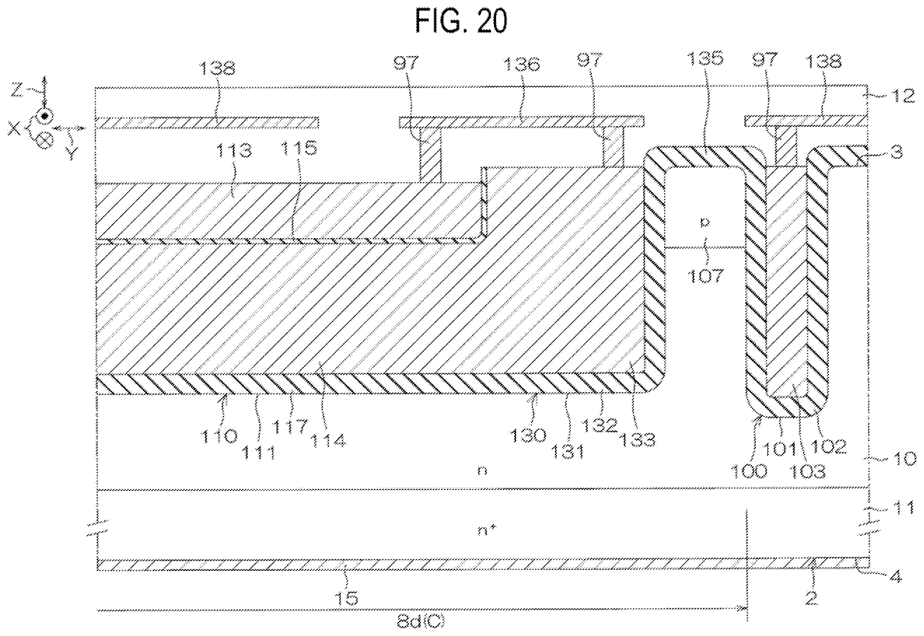

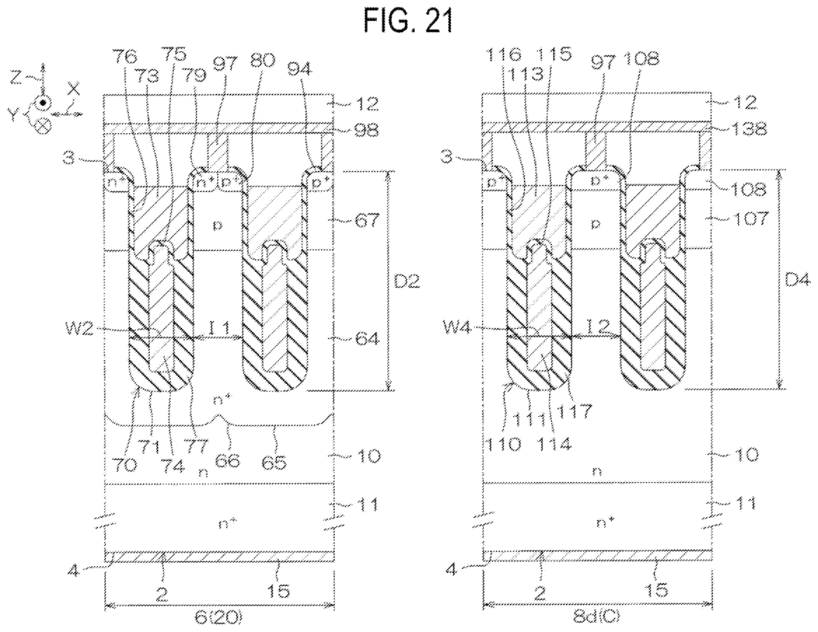

FIG. 17 is a cross-sectional view taken along line XVII-XVII in FIG. 15. FIG. 18 is a cross-sectional view taken along line XVIII-XVIII in FIG. 15. FIG. 19 is a cross-sectional view taken along line XIX-XIX in FIG. 15. FIG. 20 is a cross-sectional view taken along line XX-XX in FIG. 15. FIG. 21 is a cross-sectional view for comparing the configuration on the side of the transistor region 6 and the configuration on the side the capacitive device region 8d.

Referring to FIGS. 14 to 21, the semiconductor device 1 includes a second trench isolation structure 100 formed in the first main surface 3 to define the capacitive device region 8d. The second trench isolation structure 100 may be referred to as a “first region isolation structure.” The second trench isolation structure 100 electrically isolates the capacitive device region 8d from other regions of the transistor region 6 and the control region 7 within the chip 2. A source electric potential is applied to the second trench isolation structure 100. The second trench isolation structure 100 is formed in an annular shape surrounding the capacitive device region 8d in a plan view.

In this embodiment, the second trench isolation structure 100 is formed in a polygonal annular shape (a quadrangular annular shape, in this embodiment) having four sides parallel to the peripheral edge of the first main surface 3 in a plan view. The second trench isolation structure 100 is formed so as to be spaced apart from the bottom portion of the first semiconductor region 10 toward the first main surface 3, and faces the second semiconductor region 11 with a portion of the first semiconductor region 10 disposed between the second trench isolation structure 100 and the second semiconductor region 11.

The second trench isolation structure 100 has a third width W3. The third width W3 is the width in a direction perpendicular to the extension direction of the second trench isolation structure 100. The third width W3 may be larger than the first interval I1 of the trench gate structures 70. The third width W3 may be larger than the second width W2 of the trench gate structure 70. The third width W3 may be substantially equal to the first width W1 of the first trench isolation structure 60. Of course, the third width W3 may be larger than the first width W1 or smaller than the first width W1. In addition, the third width W3 may be substantially equal to the second width W2.

The third width W3 may be 0.4 μm or more and 2.5 μm or less. The third width W3 may have a value belonging to any one of ranges of 0.4 μm or more and 0.75 μm or less, 0.75 μm or more and 1 μm or less, 1 μm or more and 1.25 μm or less, 1.25 μm or more and 1.5 μm or less, 1.5 μm or more and 1.75 μm or less, and 1.75 μm or more and 2 μm or less. The third width W3 may be 1.25 μm or more and 1.75 μm or less.

The second trench isolation structure 100 has a third depth D3. The third depth D3 may be larger than the second depth D2 of the trench gate structure 70. The third depth D3 is substantially equal to the first depth D1 of the first trench isolation structure 60. Of course, the third depth D3 may be larger than the first depth D1 or smaller than the first depth D1. In addition, the third depth D3 may be substantially equal to the second depth D2.

The third depth D3 may be 1 μm or more and 6 μm or less. The third depth D3 may have a value belonging to any one of ranges of 1 μm or more and 2 μm or less, 2 μm or more and 3 μm or less, 3 μm or more and 4 μm or less, 4 μm or more and 5 μm or less, and 5 μm or more and 6 μm or less. The third depth D3 may be 2.5 μm or more and 4.5 μm or less.

The second trench isolation structure 100 includes a second isolation trench 101, a second isolation insulating film 102, and a second isolation electrode 103. That is, the second trench isolation structure 100 has a single electrode structure including a single electrode (second isolation electrode 103) embedded in the second isolation trench 101 and disposed between portions of an insulator (second isolation insulating film 102).

The second isolation trench 101 is formed in the first main surface 3 to define a wall surface of the second trench isolation structure 100. The second isolation insulating film 102 covers the wall surface of the second isolation trench 101. The second isolation insulating film 102 may include a silicon oxide film made of an oxide of the chip 2, or may include a silicon oxide film formed by a CVD method.

The second isolation insulating film 102 is thicker than the gate upper insulating film 76. The thickness of the second isolation insulating film 102 may be substantially equal to the thickness of the first isolation insulating film 62. The second isolation electrode 103 is embedded in the second isolation trench 101 and disposed between portions of the second isolation insulating film 102. The second isolation electrode 103 may contain conductive polysilicon.

The semiconductor device 1 includes a capacitor C formed on the first main surface 3 in the capacitive device region 8d. The following configuration is described as a component of the semiconductor device 1. However, the following configuration is also a component of the capacitor C.

The semiconductor device 1 includes a p-type (second conductivity type) capacitor region 107 formed in the surface layer portion of the first semiconductor region 10 in the capacitive device region 8d. The capacitor region 107 may have a p-type impurity concentration substantially equal to that of the body region 67. Of course, the capacitor region 107 may have a higher p-type impurity concentration than the body region 67 or a lower p-type impurity concentration than the body region 67.

The capacitor region 107 extends in a layer shape along the first main surface 3 throughout the capacitive device region 8d and is connected to the wall surface of the second trench isolation structure 100. That is, in this embodiment, the capacitor region 107 is not formed in the region outside the second trench isolation structure 100. The capacitor region 107 is formed shallower than the second trench isolation structure 100 and has a bottom portion positioned closer to the first main surface 3 than the bottom wall of the second trench isolation structure 100.

The bottom portion of the capacitor region 107 may be located closer to the first main surface 3 than the middle portion in the depth range of the second trench isolation structure 100. The capacitor region 107 may have a thickness substantially equal to the thickness of the body region 67. Of course, the thickness of the capacitor region 107 may be larger than the thickness of the body region 67 or may be smaller than the thickness of the body region 67.

The semiconductor device 1 includes a p-type high-concentration capacitor region 108 formed in the surface layer portion of the capacitor region 107 in the capacitive device region 8d.

The high-concentration capacitor region 108 has a p-type impurity concentration higher than that of the capacitor region 107. The p-type impurity concentration of the high-concentration capacitor region 108 may be substantially equal to the p-type impurity concentration of the high-concentration body region 80. The n-type impurity concentration of the high-concentration capacitor region 108 may be 1×10¹⁸ cm⁻³ or more and 1×10²¹ cm⁻³ or less. The high-concentration capacitor region 108 may be regarded as a high-concentration portion of the capacitor region 107.

The high-concentration capacitor region 108 is formed so as to be spaced apart from the bottom portion of the capacitor region 107 toward the first main surface 3, and faces the first semiconductor region 10 with a portion of the capacitor region 107 disposed between the high-concentration capacitor region 108 and the first semiconductor region 10. The high-concentration capacitor region 108 may have a thickness substantially equal to the thickness of the high-concentration body region 80. Of course, the thickness of the high-concentration capacitor region 108 may be larger than the thickness of the high-concentration body region 80 or may be smaller than the thickness of the high-concentration body region 80.

The high-concentration capacitor region 108 forms a concentration gradient in which the p-type impurity concentration increases from the bottom side of the capacitor region 107 toward the first main surface 3 within the capacitor region 107. That is, the capacitor region 107 has a concentration gradient formed by the high-concentration capacitor region 108 such that the p-type impurity concentration increases from the bottom side toward the first main surface 3 side.

The high-concentration capacitor region 108 is formed in the inner portion of the capacitive device region 8d so as to be spaced apart from the second trench isolation structure 100. Therefore, the high-concentration capacitor region 108 is surrounded by the capacitor region 107 in the capacitive device region 8d and is not in contact with the second trench isolation structure 100. The high-concentration capacitor region 108 locally increases the p-type impurity concentration of the capacitor region 107.

Unlike the configuration on the side of the transistor region 6, the semiconductor device 1 does not include an n-type impurity region in the surface layer portion of the capacitor region 107. That is, only the high-concentration capacitor region 108 is formed in the surface layer portion of the capacitor region 107, and no pentavalent element impurity region such as the n-type source region 79 is formed. That is, no channel is formed in the capacitor region 107.

Further, unlike the configuration on the side of the transistor region 6, the semiconductor device 1 does not include the high-concentration region 64 in the surface layer portion of the first semiconductor region 10 on the side of the capacitive device region 8d. That is, unlike the configuration on the side of the transistor region 6, the first semiconductor region 10 on the side of the capacitive device region 8d does not have a concentration gradient in which the impurity concentration increases from the bottom side toward the first main surface 3 side.

In other words, the first semiconductor region 10 on the side of the capacitive device region 8d does not have a concentration gradient in which the impurity concentration increases in the thickness range between the bottom portion of the first semiconductor region 10 and the trench gate structure 70. The first semiconductor region 10 on the side of the capacitive device region 8d has a substantially constant n-type impurity concentration in the thickness direction. This suppresses unwanted electric field concentration in the first semiconductor region 10 on the side of the capacitive device region 8d.

The semiconductor device 1 includes a plurality of trench structures 110 formed in the first main surface 3 in the capacitive device region 8d. Unlike the trench gate structures 70, the trench structures 110 do not contribute to channel control. The number of the trench structures 110 is less than the number of the trench gate structures 70.

The trench structures 110 are formed in the inner portion of the capacitive device region 8d so as to be spaced apart from the second trench isolation structures 100. The trench structures 110 are arranged at intervals in the first direction X and respectively formed in a stripe shape extending in the second direction Y. That is, the trench structures 110 are arranged in a stripe shape extending in the second direction Y. The length of the trench structures 110 is less than the length of the trench gate structures 70. The trench structures 110 extend across one end portion and the other end portion of the high-concentration region 64 in the longitudinal direction (second direction Y).

The trench structures 110 have a first end portion on one side in the longitudinal direction (second direction Y) and a second end portion on the other side in the longitudinal direction (second direction Y). The first end portion is located in a region between the second trench isolation structure 100 and one end of the high-concentration capacitor region 108 in a plan view. The second end is located in a region between the second trench isolation structure 100 and the high-concentration capacitor region 108 in a plan view. The trench structures 110 expose the capacitor region 107 from the regions of the first main surface 3 sandwiched between the trench structures 110.

The trench structures 110 penetrate the capacitor region 107 and the high-concentration capacitor region 108 in a cross-sectional view and are positioned in the first semiconductor region 10. The trench structures 110 are formed at intervals from the bottom portion of the first semiconductor region 10 toward the first main surface 3, and face the second semiconductor region 11 with a portion of the first semiconductor region 10 disposed between the trench structures 110 and the second semiconductor region 11.

The two trench structures 110 positioned on both sides in the first direction X may be formed in the regions outside the high-concentration capacitor region 108. That is, the outermost trench structure 110 may penetrate the capacitor region 107 at a position spaced apart from the high-concentration capacitor region 108 toward the second trench isolation structure 100, and may be located within the first semiconductor region 10.

The outermost trench structure 110 is formed so as to be spaced apart from the bottom portion of the first semiconductor region 10 toward the first main surface 3, and faces the second semiconductor region 11 with a portion of the first semiconductor region 10 disposed between the outermost trench structure 110 and the second semiconductor region 11. Of course, the outermost trench structure 110 may penetrate the capacitor region 107 and the high-concentration capacitor region 108 just like the inner trench structure 110.

The trench structures 110 have a fourth width W4 (see also FIG. 21). The fourth width W4 is the width in a direction perpendicular to the extension direction of the trench structures 110 (i.e., in the first direction X). The fourth width W4 may be smaller than the first width W1 of the first trench isolation structure 60. The fourth width W4 may be smaller than the third width W3 of the second trench isolation structure 100.

The fourth width W4 may be equal to or larger than the first interval I1 of the trench gate structures 70. The fourth width W4 is larger than the first interval I1. The fourth width W4 may be substantially equal to the second width W2 of the trench gate structure 70. Of course, the fourth width W4 may be larger than the second width W2, or may be smaller than the second width W2.

The fourth width W4 may be 0.4 μm or more and 2 μm or less. The fourth width W4 may have a value belonging to any one of ranges of 0.4 μm or more and 0.75 μm or less, 0.75 μm or more and 1 μm or less, 1 μm or more and 1.25 μm or less, 1.25 μm or more and 1.5 μm or less, 1.5 μm or more and 1.75 μm or less, and 1.75 μm or more and 2 μm or less. The fourth width W4 may be 0.8 μm or more and 1.2 μm or less.

The trench structures 110 are arranged at second intervals 12 in the first direction X (see also FIG. 21). The second interval 12 is also the mesa width (second mesa width) of the mesa portion (second mesa portion) defined in the region between the two trench structures 110 adjacent to each other. The second interval 12 may be smaller than the first width W1 of the first trench isolation structure 60. The second interval 12 may be smaller than the third width W3 of the second trench isolation structure 100.

The second interval 12 may be equal to or smaller than the second width W2 of the trench gate structure 70. The second interval 12 may be smaller than the second width W2. The second interval 12 is equal to or smaller than the fourth width W4 of the trench structure 110. The second interval 12 may be smaller than the fourth width W4.

The second interval 12 may be substantially equal to the first interval I1 of the trench gate structure 70. Of course, the second interval 12 may be larger than the first interval I1 or may be smaller than the first interval I1. The second interval 12 may be 0.5 to 4 times the first interval I1. The second interval 12 may be 2.5 times or less the first interval I1.

The second interval 12 may be 0.4 μm or more and 1.6 μm or less. The second interval 12 may have a value belonging to any one of ranges of 0.4 μm or more and 0.6 μm or less, 0.6 μm or more and 0.8 μm or less, 0.8 μm or more and 1 μm or less, 1 μm or more and 1.2 μm or less, 1.2 μm or more and 1.4 μm or less, and 1.4 μm or more and 1.6 μm or less. The second interval 12 may be 0.5 μm or more and 0.7 μm or less.

The trench structure 110 has a fourth depth D4 (see also FIG. 21). The fourth depth D4 may be substantially equal to the first depth D1 of the first trench isolation structure 60. The fourth depth D4 may be smaller than the first depth D1. The fourth depth D4 may be substantially equal to the third depth D3 of the second trench isolation structure 100. The fourth depth D4 may be smaller than the third depth D3. The fourth depth D4 may be substantially equal to the second depth D2 of the trench gate structure 70. Of course, the fourth depth D4 may be larger than the second depth D2 or smaller than the second depth D2.

The fourth depth D4 may be 1 μm or more and 6 μm or less. The fourth depth D4 may have a value belonging to any one of ranges of 1 μm or more and 2 μm or less, 2 μm or more and 3 μm or less, 3 μm or more and 4 μm or less, 4 μm or more and 5 μm or less, and 5 μm or more and 6 μm or less. The fourth depth D4 may be 2.5 μm or more and 4.5 μm or less.

In the capacitive device regions 8d, the fourth width W4, the second interval 12, and the fourth depth D4 of the trench structure 110 may be set to equal values or may be set to different values. The fourth width W4, the second interval 12, and the fourth depth D4 of the trench structure 110 are appropriately adjusted according to the electrical characteristics (capacitance value and breakdown voltage) to be achieved in each capacitive device region 8d.

An internal configuration of one trench structure 110 will be described below. The trench structure 110 includes a trench 111, an insulating film 112, an upper electrode 113, a lower electrode 114, and an intermediate insulating film 115. That is, the trench structure 110 includes an embedded electrode embedded in the trench 111 and disposed between portions of the insulating film. The embedded electrode has a multi-electrode structure including a plurality of electrodes (upper electrode 113 and lower electrode 114) vertically embedded in the trench 111.

The trench 111 is formed in the first main surface 3 to define the wall surface of the trench structure 110. The insulating film 112 covers the wall surface of the trench 111. The insulating film 112 includes an upper insulating film 116 and a lower insulating film 117. The upper insulating film 116 covers the wall surface of the trench 111 at the opening side with respect to the bottom portion of the capacitor region 107.

Specifically, the upper insulating film 116 covers the capacitor region 107 and the high-concentration capacitor region 108. The upper insulating film 116 may have a portion extending across the boundary between the first semiconductor region 10 and the capacitor region 107 to cover the first semiconductor region 10. In this case, the area of the capacitor region 107 covered by the upper insulating film 116 may be larger than the area of the first semiconductor region 10 covered by the upper insulating film 116.

The upper insulating film 116 is thinner than the first isolation insulating film 62. The thickness of the upper insulating film 116 is smaller than the thickness of the second isolation insulating film 102. The thickness of the upper insulating film 116 may be substantially equal to the thickness of the gate upper insulating film 76. Of course, the thickness of the upper insulating film 116 may be larger than the thickness of the gate upper insulating film 76 or may be smaller than the thickness of the gate upper insulating film 76. The upper insulating film 116 may include a silicon oxide film. The upper insulating film 116 may include a silicon oxide film made of an oxide of the chip 2.

The upper insulating film 116 may have a thickness of 1 nm or more and 50 nm or less. The thickness of the upper insulating film 116 may have a value belonging to any one of ranges of 1 nm or more and 5 nm or less, 5 nm or more and 10 nm or less, 10 nm or more and 15 nm or less, 15 nm or more and 20 nm or less, 20 nm or more and 25 nm or less, 25 nm or more and 30 nm or less, 30 nm or more and 35 nm or less, 35 nm or more and 40 nm or less, 40 nm or more and 45 nm or less, and 45 nm or more and 50 nm or less.

The thickness of the upper insulating film 116 may be 5 nm or more and 15 nm or less. The thickness of the upper insulating film 116 may be 5 nm or more and 10 nm or less. The thickness of the upper insulating film 116 may be 10 nm or more and 15 nm or less.

The lower insulating film 117 covers the wall surface of the trench 111 at the bottom wall side with respect to the bottom portion of the capacitor region 107. The lower insulating film 117 covers the first semiconductor region 10. The area of the first semiconductor region 10 covered by the lower insulating film 117 is larger than the area of the capacitor region 107 covered by the upper insulating film 116.

The lower insulating film 117 may have a portion that extends across the boundary between the first semiconductor region 10 and the capacitor region 107 to cover the bottom portion of the capacitor region 107. The lower insulating film 117 is thicker than the upper insulating film 116. The thickness of the lower insulating film 117 may be 10 to 50 times the thickness of the upper insulating film 116.

The thickness of the lower insulating film 117 may be substantially equal to the thickness of the gate lower insulating film 77. The thickness of the lower insulating film 117 may be substantially equal to the thickness of the first isolation insulating film 62 (second isolation insulating film 102). The lower insulating film 117 may include a silicon oxide film. The lower insulating film 117 may include a silicon oxide film made of an oxide of the chip 2, or may include a silicon oxide film formed by a CVD method.

The lower insulating film 117 may have a thickness of 100 nm or more and 500 nm or less. The thickness of the lower insulating film 117 may have a value belonging to any one of ranges of 100 nm or more and 150 nm or less, 150 nm or more and 200 nm or less, 200 nm or more and 250 nm or less, 250 nm or more and 300 nm or less, 300 nm or more and 350 nm or less, 350 nm or more and 400 nm or less, 400 nm or more and 450 nm or less, and 450 nm or more and 500 nm or less. The thickness of the lower insulating film 117 may be 200 nm or more and 250 nm or less.

The upper electrode 113 is embedded in the trench 111 at the opening side and disposed between portions of the insulating film 112 to form capacitive coupling with the capacitor region 107 through the insulating film 112. Specifically, the upper electrode 113 is embedded in the trench 111 at the opening side and disposed between portions of the upper insulating film 116, and faces the first semiconductor region 10, the capacitor region 107, and the high-concentration capacitor region 108 through the upper insulating film 116.

That is, the upper electrode 113 is embedded in the trench 111 at the opening side with respect to the bottom portion of the capacitor region 107 to form capacitive coupling with the capacitor region 107 and the high-concentration capacitor region 108 via the upper insulating film 116. The facing area of the upper electrode 113 with respect to the capacitor region 107 (high-concentration capacitor region 108) is larger than the facing area of the upper electrode 113 with respect to the first semiconductor region 10. The facing area of the upper electrode 113 with respect to the high-concentration capacitor region 108 is smaller than the facing area of the upper electrode 113 with respect to the capacitor region 107. The upper electrode 113 may contain conductive polysilicon.

The lower electrode 114 is embedded in the trench 111 at the bottom wall side and disposed between portions of the insulating film 112, and faces the first semiconductor region 10 with the insulating film 112 disposed between the lower electrode 114 and the first semiconductor region 10. Specifically, the lower electrode 114 is embedded in the trench 111 at the bottom wall side and disposed between portions of the lower insulating film 117, and faces the first semiconductor region 10 with the lower insulating film 117 disposed between the lower electrode 114 and the first semiconductor region 10. That is, the lower electrode 114 is embedded in the trench 111 at the opening side with respect to the bottom portion of the capacitor region 107. The facing area of the lower electrode 114 with respect to the first semiconductor region 10 is larger than the facing area of the upper electrode 113 with respect to the capacitor region 107.

The lower electrode 114 extends in a wall shape along the depth direction of the trench 111 (the thickness direction of the chip 2). The lower electrode 114 has an upper end portion protruding from the lower insulating film 117 toward the upper electrode 113 so as to engage with the bottom portion of the upper electrode 113. The upper end portion of the lower electrode 114 faces the upper insulating film 116 across the lower end portion of the upper electrode 113 in the lateral direction along the first main surface 3. The lower electrode 114 may contain conductive polysilicon.

The intermediate insulating film 115 is disposed between the upper electrode 113 and the lower electrode 114 to electrically insulate the upper electrode 113 and the lower electrode 114 in the trench 111. The intermediate insulating film 115 extends to the upper insulating film 116 and the lower insulating film 117. The intermediate insulating film 115 is thinner than the lower insulating film 117. The thickness of the intermediate insulating film 115 may be substantially equal to the thickness of the gate intermediate insulating film 75. The intermediate insulating film 115 may include a silicon oxide film. The intermediate insulating film 115 may include a silicon oxide film made of an oxide of the lower electrode 114.

The semiconductor device 1 includes a pair of second trench connection structures 130 connecting both end portions of a plurality of (all, in this embodiment) trench structures 110 in the capacitive device region 8d. The second trench connection structure 130 on one side connects the first end portions of a plurality of (all, in this embodiment) the trench structures 110 in an arch shape in a plan view. The second trench connection structure 130 on the other side connects the second end portions of a plurality of (all, in this embodiment) trench structures 110 in an arch shape in a plan view.

Specifically, the second trench connection structure 130 on one side has a first portion extending in the first direction X and a plurality of second portions extending in the second direction Y. The first portion faces the first end portions of the trench structures 110 in a plan view. The second portions extend from the first portion toward the first end portions so as to be connected to the first end portions.

The second trench connection structure 130 on the other side has a first portion extending in the first direction X and a plurality of second portions extending in the second direction Y. The first portion faces the second end portions of the trench structures 110 in a plan view. The second portions extend from the first portion toward the second end portions so as to be connected to the second end portions. The second trench connection structures 130 form a ladder-like trench structure together with the trench structures 110 in the capacitive device region 8d.

The second trench connection structures 130 are formed in a region between the second trench isolation structure 100 and the high-concentration capacitor region 108 so as to be spaced apart from the second trench isolation structure 100 and the high-concentration capacitor region 108. The second trench connection structures 130 are formed so as to be spaced apart from the bottom portion of the first semiconductor region 10 toward the first main surface 3, and face the second semiconductor region 11 with a portion of the first semiconductor region 10 disposed between the second trench connection structures 130 and the second semiconductor region 11.

The second trench connection structures 130 may be formed to have a width and depth substantially equal to the width and depth of the trench structures 110. Of course, the first and second portions of the second trench connection structures 130 may have different widths. For example, the second portion of the second trench connection structure 130 may be formed narrower than the first portion of the second trench connection structure 130.

In this case, the first portion may have a width substantially equal to the width of the second trench isolation structure 100, and the second portion may have a width substantially equal to the width of the trench structure 110. Further, in this case, the first portion may have a depth substantially equal to the depth of the second trench isolation structure 100, and the second portion may have a depth substantially equal to the depth of the trench structure 110.

The first portion of the second trench connection structure 130 may have a width and depth substantially equal to the width and depth of the first portion of the first trench connection structure 90. The second portion of the second trench connection structure 130 may have a width and depth substantially equal to the width and depth of the second portion of the first trench connection structure 90.

The second trench connection structure 130 on the other side has the same structure as the second trench connection structure 130 on one side except that it is connected to the second end portion of the trench structure 110. Hereinafter, a configuration of the second trench connection structure 130 on one side will be described, and the description of the configuration of the second trench connection structure 130 on the other side will be omitted.

The second trench connection structure 130 includes a second connection trench 131, a second connection insulating film 132, and a second connection electrode 133. The second connection trench 131 is formed in the first main surface 3 to define a wall surface of the second trench connection structure 130. The second connection trench 131 is connected to the trenches 111.

The second connection insulating film 132 covers the wall surface of the second connection trench 131. The second connection insulating film 132 is connected to the upper insulating film 116, the lower insulating film 117, and the intermediate insulating film 115 at the communication portion between the second connection trench 131 and the trench 111. The second connection insulating film 132 is thicker than the upper insulating film 116.

The thickness of the second connection insulating film 132 may be substantially equal to the thickness of the lower insulating film 117. The thickness of the second connection insulating film 132 may be substantially equal to the thickness of the first connection insulating film 92. The second connection insulating film 132 may include a silicon oxide film. The second connection insulating film 132 may include a silicon oxide film made of an oxide of the chip 2, or may include a silicon oxide film formed by a CVD method.

The second connection electrode 133 is embedded in the second connection trench 131 and disposed between portions of the second connection insulating film 132, and faces the first semiconductor region 10 and the capacitor region 107 through the second connection insulating film 132. The second connection electrode 133 is connected to the lower electrode 114 at the communication portion between the second connection trench 131 and the trench 111 and is electrically insulated from the upper electrode 113 by the intermediate insulating film 115. The second connection electrode 133 may be a lead portion in which the lower electrode 114 is led out from the trench 111 into the second connection trench 131. The second connection electrode 133 may contain conductive polysilicon.

The capacitor C includes a plurality of unit capacitors Cu. Each of the unit capacitors Cu includes one trench structure 110 and a capacitor region 107 (high-concentration capacitor region 108) that forms capacitive coupling with the one trench structure 110. The capacitor C is configured by a parallel circuit of the unit capacitors Cu. That is, the capacitance value of the capacitor C is a composite capacitance value of the unit capacitors Cu.

The semiconductor device 1 includes a second main surface insulating film 134 selectively covering the first main surface 3 in the capacitive device region 8d. The second main surface insulating film 134 is connected to the insulating film 112 (upper insulating film 116) and the second connection insulating film 132, and exposes the second isolation electrode 103, the upper electrode 113, and the second connection electrode 133.

The second main surface insulating film 134 is thinner than the second isolation insulating film 102. The second main surface insulating film 134 is thinner than the lower insulating film 117. The second main surface insulating film 134 is thinner than the second connection insulating film 132. The second main surface insulating film 134 may have a thickness substantially equal to that of the upper insulating film 116. The second main surface insulating film 134 may have a thickness substantially equal to that of the first main surface insulating film 94. The second main surface insulating film 134 may include a silicon oxide film. The second main surface insulating film 134 may include a silicon oxide film made of an oxide of the chip 2.

The semiconductor device 1 includes a second field insulating film 135 selectively covering the first main surface 3 inside and outside the capacitive device region 8d. The second field insulating film 135 is thicker than the second main surface insulating film 134. The second field insulating film 135 is thicker than the upper insulating film 116. The second field insulating film 135 may have a thickness substantially equal to that of the second isolation insulating film 102.

The second field insulating film 135 may have a thickness substantially equal to that of the first field insulating film 95. The second field insulating film 135 may include a silicon oxide film. The second field insulating film 135 may include a silicon oxide film made of an oxide of the chip 2, or may include a silicon oxide film formed by a CVD method.

The second field insulating film 135 covers the first main surface 3 along the inner wall of the second trench isolation structure 100 in the capacitive device region 8d and is connected to the second isolation insulating film 102, the second connection insulating film 132, and the second main surface insulating film 134. The second field insulating film 135 covers the first main surface 3 along the outer wall of the second trench isolation structure 100 outside the capacitive device region 8d and is connected to the second isolation insulating film 102.

The interlayer insulating layer 12 described above covers the second trench isolation structure 100, the trench structure 110, the second trench connection structure 130, the second main surface insulating film 134, and the second field insulating film 135 in the capacitive device region 8d.

The semiconductor device 1 includes a first wiring 136 on the first electric potential side arranged in the interlayer insulating layer 12. The first wiring 136 is a high electric potential side wiring provided on the high electric potential side. The first wiring 136 is a wiring electrically connected to the cathode of the diode Di (see FIG. 5). The first wiring 136 is electrically connected to a plurality of (all, in this embodiment) trench structures 110.

Specifically, the first wiring 136 is electrically connected to the trench structures 110 through a plurality of via electrodes 97 arranged in the interlayer insulating layer 12.

More specifically, the first wiring 136 is electrically connected to the upper electrodes 113 and the second connection electrodes 133 through the via electrodes 97. That is, the same electric potential (first electric potential) is applied to the upper electrode 113 and the lower electrode 114. This suppresses the voltage drop between the upper electrode 113 and the lower electrode 114, and suppresses unwanted electric field concentration. As a result, a decrease in breakdown voltage due to the electric field concentration is suppressed.

The semiconductor device 1 includes a second wiring 138 on the side of a second electric potential different from the first electric potential arranged in the interlayer insulating layer 12. The second wiring 138 is a low electric potential side wiring provided on the lower electric potential side than the first wiring 136. In this embodiment, the second wiring 138 is a wiring electrically connected to the boost control circuit 42 (see FIG. 5). The second wiring 138 is electrically connected to the second trench isolation structure 100, the capacitor region 107, and the high-concentration capacitor region 108.

The second wiring 138 is electrically connected to the second trench isolation structure 100, the capacitor region 107, and the high-concentration capacitor region 108 through a plurality of via electrodes 97. The via electrodes 97 for the capacitor region 107 (high-concentration capacitor region 108) are arranged in the region between adjacent trench structures 110. The via electrodes 97 for the capacitor region 107 (high-concentration capacitor region 108) are formed in a stripe shape extending along the trench structures 110 in a plan view.

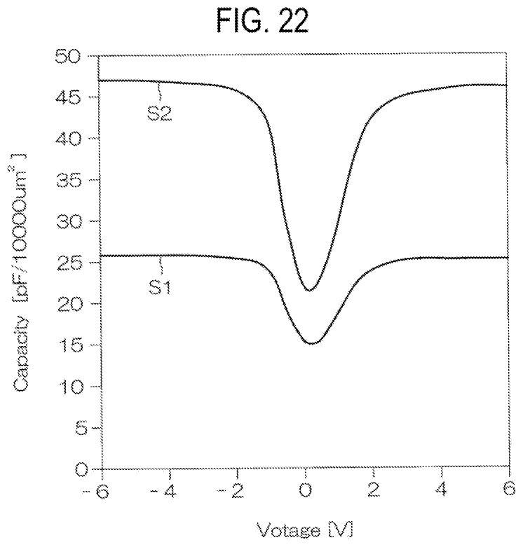

FIG. 22 is a graph showing capacitance characteristics of the capacitor C. In FIG. 22, the vertical axis indicates the capacitance value per 10,000 μm² [pF/10,000 μm²], and the horizontal axis indicates the voltage [V] across the terminals of the capacitor C. The voltage across the terminals is also the voltage between the capacitor region 107 and the trench structure 110 (upper electrode 113).

FIG. 22 shows a first characteristic S1 and a second characteristic S2. The first characteristic S1 indicates a characteristic when the frequency of the voltage across the terminals is 100 kHz. The second characteristic S2 indicates a characteristic when the frequency of the voltage across the terminals is 1 MHz. The voltage across the terminals was varied between −6V and +6V with 0 V as a reference.

Referring to the first characteristic Si, when the voltage between the terminals was +1 V or more, the capacitance value was 20 pF or more. Moreover, when the voltage across the terminals was +3 V or more, the capacitance value was 25 pF or more. The capacitance value was 20 pF or more and 30 pF or less in the voltage range of +1 V or more and +6 V or less.

On the other hand, when the voltage across the terminals was −1 V or less, the capacitance value was 20 pF or more. Further, when the voltage across the terminals was −3 V or less, the capacitance value was 25 pF or more. The capacitance value was 20 pF or more and 30 pF or less in the voltage range of −6 V or more and −1 V or less. That is, in the first characteristic Si, the capacitance value was 20 pF or more and 30 pF or less in the absolute voltage range of 1 V or more and 6 V or less.

Referring to the second characteristic S2, when the voltage across the terminals was +1 V or more, the capacitance value was 40 pF or more. Moreover, when the voltage across the terminals was +3 V or more, the capacitance value was 45 pF or more. The capacitance value was 40 pF or more and 50 pF or less in the voltage range of +1 V or more and +6 V or less.

On the other hand, when the voltage across the terminals was −1 V or less, the capacitance value was 40 pF or more. On the other hand, when the voltage across the terminals was −3 V or less, the capacitance value was 45 pF or more. The capacitance value was 40 pF or more and 50 pF or less in the voltage range of −6 V or more and −1 V or less. That is, in the second characteristic S2, the capacitance value was 40 pF or more and 50 pF or less in the absolute voltage range of 1 V or more and 6 V or less.

Referring to the first characteristic S1 and the second characteristic S2, the capacitor C was not destroyed in the voltage range of ±6 V. That is, the capacitor C has a breakdown voltage of 6V or more. The breakdown voltage of the capacitor C may be 3 V or more and 50 V or less. The breakdown voltage of the capacitor C may have a value belonging to any one of ranges of 3 V or more and 5 V or less, 5 V or more and 10 V or less, 10 V or more and 20 V or less, 20 V or more and 30 V or less, 30 V or more and 40 V or less, and 40 V or more and 50 V or less. The breakdown voltage of the capacitor C can be regulated by adjusting the thickness of the insulating film 112 (specifically, the thickness of the upper insulating film 116).

As described above, the semiconductor device 1 includes the n-type (first conductivity type) first semiconductor region 10, the p-type (second conductivity type) capacitor region 107, and the trench structure 110. The first semiconductor region 10 has a first main surface 3. The capacitor region 107 is formed in the surface layer portion of the first main surface 3. The trench structure 110 includes a trench 111, an insulating film 112, and an embedded electrode.

The trench 111 is formed in the first main surface 3 so as to penetrate the capacitor region 107. The insulating film 112 covers the wall surface of the trench 111. The embedded electrode is embedded in the trench 111 so as to form capacitive coupling with the capacitor region 107 via the insulating film 112. With this configuration, the capacitor C can be formed between the capacitor region 107 and the trench structure 110. Therefore, it is possible to provide a semiconductor device 1 including a capacitor C having a novel layout.

The embedded electrode may have a multi-electrode structure including an upper electrode 113 embedded in the trench 111 at the opening side and disposed between portions of the insulating film 112, and a lower electrode 114 embedded in the trench 111 at the bottom wall side and disposed between portions of the insulating film 112. According to this configuration, a capacitor C can be formed between the capacitor region 107 and the trench structure 110 having the multi-electrode structure.

In this case, the upper electrode 113 may be embedded in the trench 111 at the opening side with respect to the bottom portion of the capacitor region 107 so as to form capacitive coupling with the capacitor region 107 through the insulating film 112. On the other hand, the lower electrode 114 may be embedded in the trench 111 at the bottom wall side with respect to the bottom portion of the capacitor region 107 so as to face the first semiconductor region 10 through the insulating film 112. With this configuration, a capacitor C can be formed between the capacitor region 107 and the upper electrode 113.

The insulating film 112 may include an upper insulating film 116 covering the wall surface of the trench 111 at the opening side, and a lower insulating film 117 having a thickness larger than that of the upper insulating film 116 and covering the wall surface of the trench 111 at the bottom wall side. In this case, the upper electrode 113 may be embedded in the trench 111 at the opening side and disposed between portions of the upper insulating film 116. On the other hand, the lower electrode 114 is embedded in the trench 111 at the bottom wall side and disposed between portions of the lower insulating film 117.

According to this configuration, the upper electrode 113 forms capacitive coupling with the capacitor region 107 via the upper insulating film 116 thinner than the lower insulating film 117. Therefore, the capacitance value of the capacitor C can be increased. The breakdown voltage of the capacitor C is regulated by adjusting the thickness of the upper insulating film 116. On the other hand, since the lower insulating film 117 is formed thicker than the upper insulating film 116, the breakdown voltage of the trench structure 110 can be increased by the lower insulating film 117.

The trench structure 110 may include an intermediate insulating film 115 disposed between the upper electrode 113 and the lower electrode 114. According to this configuration, the upper electrode 113 and the lower electrode 114 can be electrically insulated by the intermediate insulating film 115 in the trench 111. Accordingly, the capacitor C can be properly formed between the capacitor region 107 and the upper electrode 113.

A first electric potential may be applied to the capacitor region 107, and a second electric potential different from the first electric potential may be applied to the upper electrode 113. In this case, the second electric potential may be applied to the lower electrode 114. With this configuration, it is possible to suppress the voltage drop between the upper electrode 113 and the lower electrode 114 via the intermediate insulating film 115. Therefore, it is possible to suppress unwanted electric field concentration between the upper electrode 113 and the lower electrode 114.

The trench structures 110 may be formed at intervals in the first main surface 3. According to this configuration, the capacitance value of the capacitor region 107 can be adjusted by the trench structures 110. In addition, the breakdown voltage of the capacitor C can be increased by the trench structures 110.

The semiconductor device 1 may include a high-concentration capacitor region 108. In this case, the high-concentration capacitor region 108 has an impurity concentration higher than that of the capacitor region 107 and is formed in the surface layer portion of the capacitor region 107. In such a configuration, the trench 111 is formed in first main surface 3 so as to penetrate the capacitor region 107 and the high-concentration capacitor region 108.

The embedded electrode (specifically, the upper electrode 113) in the trench 111 forms capacitive coupling with the capacitor region 107 and the high-concentration capacitor region 108 through the insulating film 112. According to this configuration, the capacitors C can be formed in the region between the capacitor region 107 and the trench structure 110 and in the region between the high-concentration capacitor region 108 and the trench structure 110.

The semiconductor device 1 may include a first wiring 136 and a second wiring 138. The first wiring 136 is electrically connected to the trench structure 110 on the first main surface 3. The second wiring 138 is electrically connected to the capacitor region 107 on the first main surface 3. With this configuration, an electric signal can be applied to the capacitor C via the first wiring 136 and the second wiring 138.

The semiconductor device 1 may include a capacitive device region 8d provided on the first main surface 3 and a second trench isolation structure 100 (region isolation structure) formed on the first main surface 3 so as to electrically isolate the capacitive device region 8d from other regions. In this case, the capacitor region 107 is formed in the capacitive device region 8d, and the trench structure 110 is formed in the capacitive device region 8d. With this configuration, the capacitor C can be formed in the capacitive device region 8d which is electrically independent from other regions. That is, since the electrical influence from other regions on the capacitor C can be reduced, it is possible to improve the electrical characteristics of the capacitor C.

The semiconductor device 1 may include a transistor region 6 provided on the first main surface 3 and a capacitive device region 8d provided on the first main surface 3 so as to be spaced apart from the transistor region 6. In this case, the capacitor region 107 is formed in the capacitive device region 8d, and the trench structure 110 is formed in the capacitive device region 8d. According to this configuration, the capacitor C can be formed in the capacitive device region 8 d which is electrically independent from the transistor region 6.

That is, since the electrical influence of the transistor region 6 on the capacitor C can be reduced, it is possible to improve the electrical characteristics of the capacitor C in the configuration including the transistor region 6 and the capacitive device region 8d. Moreover, since the electrical influence of the capacitive device region 8d on the transistor region 6 can be reduced, it is possible to improve the electrical characteristics of the transistor region 6 in the configuration including the transistor region 6 and the capacitive device region 8d. The capacitive device region 8d may have a plan-view area smaller than that of the transistor region 6.

The semiconductor device 1 may include an output transistor 20 in the transistor region 6. The output transistor 20 includes a body region 67 and a trench gate structure 70 in the transistor region 6. The body region 67 is formed in the surface layer portion of the first main surface 3. The trench gate structure 70 includes a gate trench 71, a gate insulating film 72, and a gate embedded electrode.

The gate trench 71 is formed in the first main surface 3 so as to penetrate the body region 67. The gate insulating film 72 covers the wall surface of the gate trench 71. The gate embedded electrode is embedded in the gate trench 71 and disposed between portions of the gate insulating film 72. According to this configuration, it is possible to provide the semiconductor device 1 having the trench gate type output transistor 20 in the transistor region 6. Moreover, according to such a configuration, the trench structure 110 can be formed simultaneously with the step of forming the trench gate structure 70.

The gate embedded electrode may have a multi-electrode structure including an upper gate electrode 73 embedded in the gate trench 71 at the opening side and disposed between portions of the gate insulating film 72, and a lower gate electrode 74 embedded in the gate trench 71 at the bottom wall side and disposed between portions of the gate insulating film 72. According to this configuration, it is possible to form the trench gate structure 70 having a multi-electrode structure. Such a configuration may be applied together with the trench structure 110 having a multi-electrode structure.

In this case, the gate upper electrode 73 may be embedded in the gate trench 71 at the opening side with respect to the bottom portion of the body region 67 so as to face the body region 67 through the gate insulating film 72. On the other hand, the gate lower electrode 74 may be embedded in the gate trench 71 at the bottom wall side with respect to the bottom portion of the body region 67 so as to face the first semiconductor region 10 through the gate insulating film 72.

The gate insulating film 72 may include a gate upper insulating film 76 covering the wall surface of the gate trench 71 at the opening side, and a gate lower insulating film 77 covering the wall surface of the gate trench 71 at the bottom wall side with a thickness larger than that of the gate upper insulating film 76. In this case, the gate upper electrode 73 may be embedded in the gate trench 71 at the opening side and disposed between portions of the gate upper insulating film 76. On the other hand, the gate lower electrode 74 may be embedded in the gate trench 71 at the bottom wall side and disposed between portions of the gate lower insulating film 77.

The trench gate structure 70 may include a gate intermediate insulating film 75 disposed between the gate upper electrode 73 and the gate lower electrode 74. According to this configuration, the gate upper electrode 73 and the gate lower electrode 74 can be electrically insulated by the gate intermediate insulating film 75 in the gate trench 71.

A gate electric potential (gate signal) may be applied to the gate upper electrode 73 and a gate electric potential (gate signal) may be applied to the gate lower electrode 74 together with the gate lower electrode 73. With this configuration, it is possible to suppress a voltage drop between the gate upper electrode 73 and the gate lower electrode 74 via the intermediate insulating film 115. Thus, it is possible to suppress unwanted electric field concentration between the gate upper electrode 73 and the gate lower electrode 74. A plurality of trench gate structures 70 may be formed at intervals on the first main surface 3.

The semiconductor device 1 may include an n-type source region 79 formed in a region along the trench gate structure 70 in the surface layer portion of the body region 67. The semiconductor device 1 may include a p-type high-concentration body region 80 formed in a region along the trench gate structure 70 in the surface layer portion of the body region 67.

The output transistor 20 may be a variable on-resistance gate split transistor. In other words, the output transistor 20 may include a plurality of system transistors 21 formed on the first main surface 3 so as to be individually controllable, and may be configured to generate a single output current Io by selective control of the system transistors 21. According to such a configuration, it is possible to provide the output transistor 20 in which the on-resistance (channel utilization rate) is changed by individual control of the system transistors 21.

First and second modifications of the transistor region 6 will be described below. The first and second modifications may be applied to the transistor region 6 individually, or may be applied to the transistor region 6 in combination.

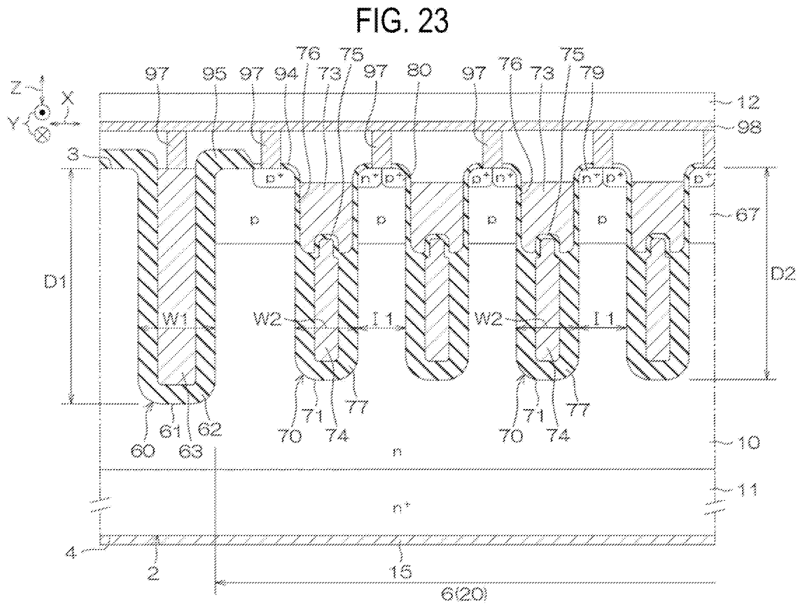

FIG. 23 is a cross-sectional view showing a first modification of the transistor region 6. In the above-described embodiment, the transistor region 6 (output transistor 20) includes the high-concentration region 64. In contrast, the transistor region 6 according to the first modification does not include the high-concentration region 64. That is, the first semiconductor region 10 of the transistor region 6 does not have a concentration gradient in which the impurity concentration increases from the bottom side toward the first main surface 3 side.

In other words, the first semiconductor region 10 on the transistor region 6 side does not have a concentration gradient in which the impurity concentration increases in the thickness range between the bottom portion of the first semiconductor region 10 and the trench gate structure 70. The first semiconductor region 10 on the transistor region 6 side has a substantially constant n-type impurity concentration in the thickness direction.

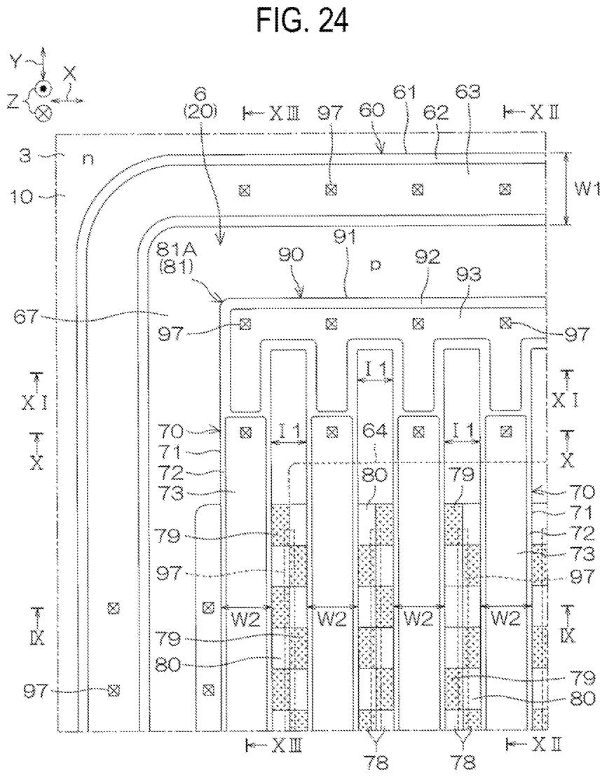

FIG. 24 is a plan view showing a second modification of the transistor region 6. In the above-described embodiment, there has been described the output transistor 20 in which the first trench connection structures 90 are formed to connect both end portions of a particular trench gate structure 70 to be organized (grouped), and which includes the system transistors 21.

However, one series of output transistors 20 may be adopted. In this case, the second system transistor 21B is formed as the first system transistor 21A, and all the trench gate structures 70 are on/off controlled at the same time. Furthermore, in such a structure, as shown in FIG. 24, the first trench connection structures 90 may connect both end portions of all the trench gate structures 70.

The first trench connection structure 90 on one side connects the first end portions of all the trench gate structures 70 in an arch shape in a plan view. The first trench connection structure 90 on the other side connects the second end portions of all the trench gate structures 70 in an arch shape in a plan view. Otherwise, the configuration of the first trench connection structure 90 is the same as in the above-described embodiment.

First and second modifications of the capacitive device region 8d will be described below. The first and second modifications may be applied to the capacitive device region 8d individually, or may be applied to the transistor region 6 in combination.

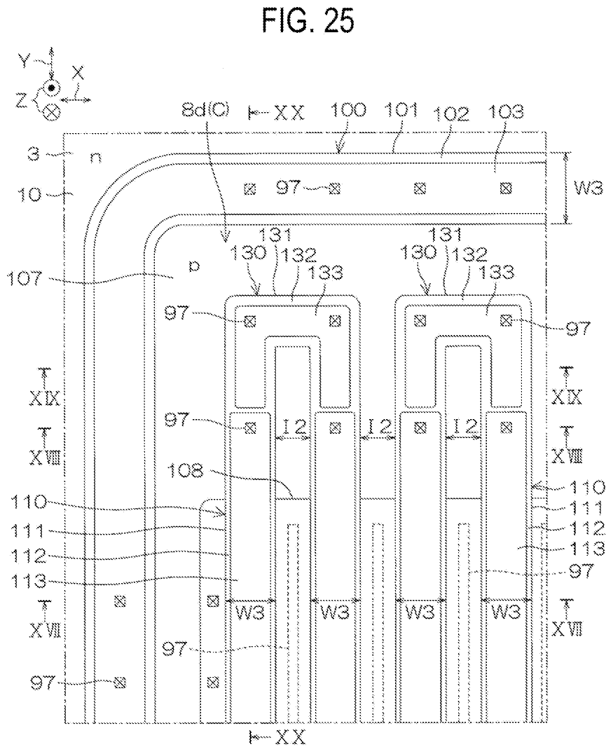

FIG. 25 is a plan view showing a first modification of the capacitive device region 8d. In the above-described embodiment, there has been described the example in which a pair of second trench connection structures 130 connecting both end portions of all the trench structures 110 in an arch shape is formed in the capacitive device region 8d.

However, the second trench connection structures 130 may have the same form as the first trench connection structures 90. That is, the second trench connection structures 130 may be provided on the first end side of the trench structure 110, and the second trench connection structures 130 may be provided on the second end side of the trench structure 110.

Each second trench connection structure 130 on the first end side connects the first end portions of a plurality of (two, in this embodiment) trench structures 110 in an arch shape in a plan view. Each second trench connection structure 130 on the first end side has a first portion extending in the first direction X and a plurality of (two, in this embodiment) second portions extending in the second direction Y. The first portion faces the first end portions of the trench structures 110 in a plan view. The second portions extend from the first portion toward the first end portions so as to be connected to the first end portions.

Each second trench connection structure 130 on the second end side connects the second end portions of a plurality of (two, in this embodiment) trench structures 110 to which each first trench connection structure 90 is connected, in an arch shape in a plan view. Each second trench connection structure 130 on the second end side has a first portion extending in the first direction X and a plurality of (two, in this embodiment) second portions extending in the second direction Y. The first portion faces the second end portions of the trench structures 110 in a plan view. The second portions extend from the first portion toward the second end portions so as to be connected to the second end portions.

Thus, the second trench connection structure 130 on the first end side and the second trench connection structure 130 on the second end side constitute a plurality of corresponding trench structures 110 and one annular or ladder-like trench structure. Otherwise, the configuration of the second trench connection structure 130 is the same as in the above-described embodiment.

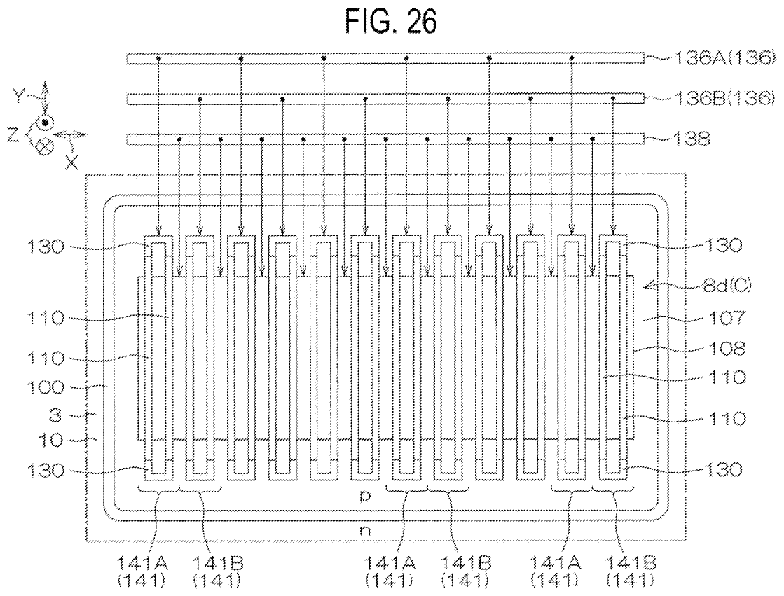

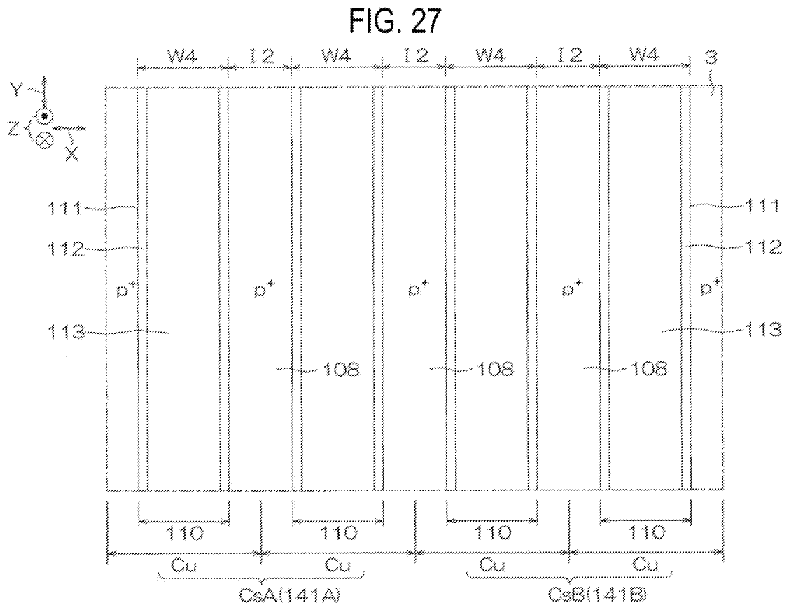

FIG. 26 is a plan view showing a second modification of the capacitive device region 8d. FIG. 27 is an enlarged plan view showing a main part of the capacitive device region 8d shown in FIG. 26. Referring to FIGS. 26 and 27, in the configuration of the first modification shown in FIG. 25, the capacitor C may include a plurality of capacitive block regions 141 provided in the capacitive device region 8d. The capacitive block regions 141 include a plurality of first capacitive block regions 141A and a plurality of second capacitive block regions 141B.

The first capacitive block regions 141A are regions in which one or a plurality of (a plurality of, in this embodiment) unit capacitors Cu for a first system capacitor CsA are arranged. The second capacitive block regions 141B are regions in which one or a plurality of (a plurality of, in this embodiment) unit capacitors Cu for a second system capacitor CsB are arranged.

The first capacity block regions 141A are arranged at intervals in the first direction X. The number of unit capacitors Cu in each first capacitive block region 141A is arbitrary. In this embodiment, two unit capacitors Cu are arranged in each first capacitive block region 141A. As the number of unit capacitors Cu in each first capacitive block region 141A increases, the amount of heat generated in each first capacitive block region 141A increases. Therefore, the number of unit capacitors Cu in each first capacitive block region 141A may be two or more and five or less.

The second capacitive block regions 141B are arranged alternately with the first capacitive block regions 141A along the first direction X so as to sandwich one first capacitive block region 141A. As a result, the heat generation locations caused by the first capacitive block regions 141A can be thinned out by the second capacitive block regions 141B, and the heat generation locations caused by the second capacitive block regions 141B can be thinned out by the first capacitive block regions 141A.

The number of unit capacitors Cu in each second capacitive block region 141B is arbitrary. In this embodiment, two unit capacitors Cu are arranged in each second capacitive block region 141B. As the number of unit capacitors Cu in each second capacitive block region 141B increases, the amount of heat generated in each second capacitive block region 141B increases.

Therefore, the number of unit capacitors Cu in each second capacitive block region 141B may be two or more and five or less. Considering the in-plane temperature variations in the transistor region 6, the number of unit capacitors Cu in the second capacitive block region 141B may be the same as the number of unit capacitors Cu in the first capacitive block region 141A.

The second trench connection structures 130 described above connect both end portions of a plurality of (two, in this embodiment) trench structures 110 to be systematized (grouped) in each capacitive block region 141.

In this embodiment, the semiconductor device 1 includes a plurality of first wirings 136 arranged within the interlayer insulating layer 12. The first wirings 136 include a first system wiring 136A and a second system wiring 136B. The first system wiring 136A is electrically connected to the first system capacitor CsA and electrically isolated from the second system capacitor CsB. The second system wiring 136B is electrically connected to the second system capacitor CsB and electrically separated from the first system capacitor CsA.

The first system wiring 136A is electrically connected to the corresponding trench structures 110 and the corresponding second trench connection structures 130 through the via electrodes 97 arranged in the interlayer insulating layer 12. Specifically, the first system wiring 136A is electrically connected to the corresponding gate upper electrodes 73 and the corresponding first connection electrodes 93 through the via electrodes 97.

The second system wiring 136B is electrically connected to the corresponding trench structures 110 and the corresponding second trench connection structures 130 through the via electrodes 97 arranged in the interlayer insulating layer 12. Specifically, the second system wiring 136B is electrically connected to the corresponding gate upper electrodes 73 and the corresponding first connection electrodes 93 through the via electrodes 97.

According to the capacitive device region 8d of the second modification, it is possible to provide a variable capacitance value capacitor C. That is, according to such a configuration, it is possible to individually control the on/off of the first system capacitor CsA and individually control the on/off of the second system capacitor CsB. That is, the first system capacitor CsA can be individually controlled while being electrically independent of the second system capacitor CsB, and the second system capacitor CsB can be individually controlled while being electrically independent of the first system capacitor CsA.

That is, the capacitor C can be controlled so that both the first system capacitor CsA and the second system capacitor CsB are turned on at the same time. Further, the capacitor C can be controlled so that the first system capacitor CsA is turned on while the second system capacitor CsB is turned off. In addition, the capacitor C can be controlled so that the first system capacitor CsA is turned off while the second system capacitor CsB is turned on.

The capacitance value of the second system capacitor CsB may be substantially equal to the capacitance value of the first system capacitor CsA. Of course, the capacitance value of the second system capacitor CsB may be larger than the capacitance value of the first system capacitor CsA. In addition, the capacitance value of the second system capacitor CsB may be smaller than the capacitance value of the first system capacitor CsA.

The embodiment described above can be embodied in yet other forms. For example, in the above-described embodiment, there has been described the example in which the transistor region 6 and the control region 7 are formed in one chip 2. However, the configuration of the semiconductor device 1 is arbitrary as long as the semiconductor device 1 has the capacitive device region 8d.

For example, a semiconductor device 1 having only a single or a plurality of capacitive device regions 8d and having no other region than the transistor region 6 and the control region 7 may be adopted. For example, a semiconductor device 1 having only the control region 7 and not having the transistor region 6 may be adopted. For example, a semiconductor device 1 having the transistor region 6 and the capacitive device region 8d and having no other region than the control region 7 may be adopted.

In the above-described embodiment, two series of output transistors 20 have been described. However, three or more series of output transistors 20 may be adopted. In this case, a plurality of block regions 81 for system transistors constituting three or more series of output transistors 20 are provided, and three or more series of gate wirings 96 corresponding to the block regions 81 are provided.

In the above-described embodiment, the configuration having the current monitor circuit 25 has been described. The current monitor circuit 25 may be formed by using at least one unit transistor 22 out of the plurality of unit transistors 22.

In the above-described embodiment, there has been described the example in which the gate upper electrode 73 and the gate lower electrode 74 are at the same electric potential. However, a source electric potential may be applied to the gate lower electrode 74. In this case, the source wiring 98 is electrically connected to the first connection electrode 93 through the via electrode 97.

In the above-described embodiment, there has been described the example in which the upper electrode 113 and the lower electrode 114 are at the same electric potential. However, a source electric potential may be applied to the lower electrode 114. In this case, the second wiring 138 is electrically connected to the second connection electrode 133 through the via electrode 97.

In the above-described embodiment, there has been described the example in which the second trench isolation structure 100 is electrically connected to the second wiring 138. However, the second trench isolation structure 100 may be electrically connected to the source wiring 98 instead of the second wiring 138.

In the above-described embodiment, there has been described the example in which the trench gate structures 70 are arranged in a stripe shape extending in the second direction Y and the trench structures 110 are arranged in a stripe shape extending in the second direction Y. However, the trench structures 110 may extend in a direction different from the extension direction of the trench gate structures 70.

For example, the trench gate structures 70 may be arranged in a stripe shape extending in the second direction Y, and the trench structures 110 may be arranged in a stripe shape extending in the first direction X. For example, the trench gate structures 70 may be arranged in a stripe shape extending in the first direction X, and the trench structures 110 may be arranged in a stripe shape extending in the second direction Y.

In the above-described embodiment, there has been described the example in which the source terminal 13 is formed of an output terminal and the drain terminal 15 is formed of a power source terminal. However, a form in which the source terminal 13 is a ground terminal and the drain terminal 15 is an output terminal may be adopted. In this case, the semiconductor device 1 serves as a low-side switching device electrically disposed between the load (inductive load L) and the ground.

In the above-described embodiment, there has been described the example which the first conductivity type is an n-type and the second conductivity type is a p-type. However, the first conductivity type may be a p-type and the second conductivity type may be an n-type. The specific configuration in this case can be obtained by replacing the n-type regions with p-type regions and replacing the p-type regions with n-type regions in the above description and the accompanying drawings.

In the above-described embodiment, the first direction X and the second direction Y are defined by the extension directions of the first to fourth side surfaces 5A to 5D. However, the first direction X and the second direction Y may be arbitrary directions as long as they maintain a mutually intersecting relationship (specifically, orthogonal relationship). For example, the first direction X may be the extension direction of the third side surface 5C (fourth side surface 5D), and the second direction Y may be the extension direction of the first side surface 5A (second side surface 5B). Further, the first direction X may be a direction intersecting the first to fourth side surfaces 5A to 5D, and the second direction Y may be a direction intersecting the first to fourth side surfaces 5A to 5D.

The following are examples of features extracted from this specification and the accompanying drawings. In the following, alphanumeric characters in parentheses represent corresponding components in the above-described embodiment. However, this is not intended to limit the scope of each item (Clause) to the embodiment. The “semiconductor device” in the following clauses may be replaced by a “semiconductor switching device,” a “semiconductor control device,” a “semiconductor module,” an “electronic circuit,” a “semiconductor circuit,” an “intelligent power device,” an “intelligent power module,” an “intelligent power switch,” or the like.
[A1] A semiconductor device (1), comprising: a semiconductor region (10) of a first conductivity type (n-type) having a main surface (3); a capacitor region (107) of a second conductivity type (p-type) formed in a surface layer portion of the main surface (3); and at least one trench structure (110) including a trench (111) formed in the main surface (3) to penetrate the capacitor region (107), an insulating film (112) covering a wall surface of the trench (111), and embedded electrodes (113 and 114) embedded in the trench (111) so as to form capacitive coupling with the capacitor region (107) through the insulating film (112).
[A2] The semiconductor device (1) of A1, wherein the embedded electrodes (113 and 114) have a multi-electrode structure including an upper electrode (113) embedded in the trench (111) at an opening side and disposed between portions of the insulating film (112), and a lower electrode (114) embedded in the trench (111) at a bottom wall side and disposed between portions of the insulating film (112).
[A3] The semiconductor device (1) of A2, wherein the upper electrode (113) is embedded in the trench (111) at the opening side with respect to a bottom portion of the capacitor region (107) so as to form the capacitive coupling with the capacitor region (107) through the insulating film (112), and wherein the lower electrode (114) is embedded in the trench (111) at the bottom wall side with respect to the bottom portion of the capacitor region (107) so as to face the semiconductor region (10) through the insulating film (112).
[A4] The semiconductor device (1) of A2 or A3, wherein the insulating film (112) includes an upper insulating film (116) covering the wall surface of the trench (111) at the opening side, and a lower insulating film (117) covering the wall surface of the trench (111) at the bottom wall side with a thickness larger than the thickness of the upper insulating film (116), wherein the upper electrode (113) is embedded in the trench (111) at the opening side and disposed between portions of the upper insulating film (116), and wherein the lower electrode (114) is embedded in the trench (111) at the bottom wall side and disposed between portions of the lower insulating film (117).
[A5] The semiconductor device (1) of any one of A2 to A4, wherein the at least one trench structure (110) includes an intermediate insulating layer (115) disposed between the upper electrode (113) and the lower electrode (114).
[A6] The semiconductor device (1) of A5, wherein a first electric potential is applied to the capacitor region (107), and wherein a second electric potential different from the first electric potential is applied to the upper electrode (113).
[A7] The semiconductor device (1) of any one of A1 to A6, wherein the at least one trench structure includes a plurality of the trench structures (110) formed at intervals in the main surface (3).
[A8] The semiconductor device (1) of any one of A1 to A7, further comprising: a high-concentration capacitor region (108) of the second conductivity type (p-type) having an impurity concentration higher than an impurity concentration of the capacitor region (107) and being formed in a surface layer portion of the capacitor region (107), wherein the trench (111) is formed in the main surface (3) so as to penetrate the capacitor region (107) and the high-concentration capacitor region (108), and wherein the embedded electrodes (113 and 114) form the capacitive coupling with the capacitor region (107) and the high-concentration capacitor region (108) through the insulating film (112).
[A9] The semiconductor device (1) of any one of A1 to A8, further comprising: a first wiring (136) electrically connected to the at least one trench structure (110) on the main surface (3); and a second wiring (138) electrically connected to the capacitor region (107) on the main surface (3).
[A10] The semiconductor device (1) of any one of A1 to A9, further comprising: a capacitive device region (8d) provided on the main surface (3); and a region isolation structure (100) formed on the main surface (3) so as to electrically isolate the capacitive device region (8d) from other regions, wherein the capacitor region (107) is formed on the capacitive device region (8d), and wherein the at least one trench structure (110) is formed on the capacitive device region (8d).
[A11] The semiconductor device (1) of any one of A1 to A9, further comprising: a transistor region (6) provided on the main surface (3); and a capacitive device region (8d) provided on the main surface (3), wherein the capacitor region (107) is formed on the capacitive device region (8d), and wherein the at least one trench structure (110) is formed on the capacitive device region (8d).
[A12] The semiconductor device (1) of A11, wherein the capacitive device region (8d) has a plan-view area smaller than a plan-view area of the transistor region (6).
[A13] The semiconductor device (1) of A11 or A12, wherein the transistor region (6) includes: a body region (67) of the second conductivity type (p-type) formed in the surface layer portion of the main surface (3); and at least one trench gate structure (70) including a gate trench (71) formed in the main surface (3) so as to penetrate the body region (67), a gate insulating film (72) covering a wall surface of the gate trench (71), and gate electrodes (73 and 74) embedded in the gate trench (71) and disposed between portions of the gate insulating film (72).
[A14] The semiconductor device (1) of A13, wherein the gate electrodes (73 and 74) have a multi-electrode structure including a gate upper electrode (73) embedded in the gate trench (71) at an opening side and disposed between portions of the gate insulating film (72), and a gate lower electrode (74) embedded in the gate trench (71) at a bottom wall side and disposed between portions of the gate insulating film (72).
[A15] The semiconductor device (1) of A14, wherein the gate upper electrode (73) is embedded in the gate trench (71) at the opening side with respect to a bottom portion of the body region (67) so as to face the body region (67) through the gate insulating film (72), and wherein the gate lower electrode (74) is embedded in the gate trench (71) at the bottom wall side with respect to the bottom portion of the body region (67) so as to face the semiconductor region (10) through the gate insulating film (72).
[A16] The semiconductor device (1) of A14 or A15, wherein the gate insulating film (72) includes a gate upper insulating film (76) covering the wall surface of the gate trench (71) at the opening side, and a gate lower insulating film (77) covering the wall surface of the gate trench (71) at the bottom wall side with a thickness larger than a thickness of the gate upper insulating film (76), wherein the gate upper electrode (73) is embedded in the gate trench (71) at the opening side and disposed between portions of the gate upper insulating film (76), and wherein the gate lower electrode (74) is embedded in the gate trench (71) at the bottom wall side and disposed between portions of the gate lower insulating film (77).
[A17] The semiconductor device (1) of any one of A14 to A16, wherein the at least one trench gate structure (70) includes a gate intermediate insulating film (75) disposed between the gate upper electrode (73) and the gate lower electrode (74).
[A18] The semiconductor device (1) of any one of A13 to A17, further comprising: a source region (79) of the first conductivity type (n-type) formed in a region provided along the at least one trench gate structure (70) at the surface layer portion of the body region (67).
[A19] The semiconductor device (1) of any one of A13 to A18, further comprising: a high-concentration body region (80) of the second conductivity type (p-type) having an impurity concentration higher than an impurity concentration of the body region (67) and being formed in a region provided along the at least one trench gate structure (70) at the surface layer portion of the body region (67).
[A20] The semiconductor device (1) of any one of A13 to A19, wherein the at least one trench gate structure (70) includes a plurality of the trench gate structures formed at intervals in the main surface (3).
[A21] The semiconductor device (1) of any one of A1 to A9, further comprising: a transistor region (6) provided on the main surface (3); a capacitive device region (8d) provided on the main surface (3); and an output transistor (20) formed in the transistor region (6), wherein the capacitor region (107) is formed in the capacitive device region (8d), and wherein the at least one trench structure (110) is formed in the capacitive device region (8d).
[A22] The semiconductor device (1) of A21, wherein the output transistor (20) includes a plurality of system transistors (21, 21A and 21B) individually controllably formed on the first main surface (3), and wherein the output transistor (20) is configured to generate a single output signal (Io) by selective control of the system transistors (21, 21A and 21B).
[A23] The semiconductor device (1) of A22, wherein the output transistor (20) is configured such that an on-resistance is changed by individual control of the system transistors (21, 21A and 21B).

Although the embodiments have been described in detail above, these are nothing more than specific examples for clarifying technical content. Various technical ideas extracted from this specification can be appropriately combined without being limited by the order of descriptions in the specification.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor region of a first conductivity type having a main surface;
a capacitor region of a second conductivity type formed in a surface layer portion of the main surface; and
at least one trench structure including a trench formed in the main surface to penetrate the capacitor region, an insulating film covering a wall surface of the trench, and embedded electrodes embedded in the trench so as to form capacitive coupling with the capacitor region through the insulating film.

2. The semiconductor device of claim 1, wherein the embedded electrodes have a multi-electrode structure including an upper electrode embedded in the trench at an opening side and disposed between portions of the insulating film, and a lower electrode embedded in the trench at a bottom wall side and disposed between portions of the insulating film.

3. The semiconductor device of claim 2, wherein the upper electrode is embedded in the trench at the opening side with respect to a bottom portion of the capacitor region so as to form the capacitive coupling with the capacitor region through the insulating film, and wherein the lower electrode is embedded in the trench at the bottom wall side with respect to the bottom portion of the capacitor region so as to face the semiconductor region through the insulating film.

4. The semiconductor device of claim 2, wherein the insulating film includes an upper insulating film covering the wall surface of the trench at the opening side, and a lower insulating film covering the wall surface of the trench at the bottom wall side with a thickness larger than a thickness of the upper insulating film,
wherein the upper electrode is embedded in the trench at the opening side and disposed between portions of the upper insulating film, and
wherein the lower electrode is embedded in the trench at the bottom wall side and disposed between portions of the lower insulating film.

5. The semiconductor device of claim 2, wherein the at least one trench structure includes an intermediate insulating layer disposed between the upper electrode and the lower electrode.

6. The semiconductor device of claim 5, wherein a first electric potential is applied to the capacitor region, and
wherein a second electric potential different from the first electric potential is applied to the upper electrode.

7. The semiconductor device of claim 1, wherein the at least one trench structure includes a plurality of trench structures formed at intervals in the main surface.

8. The semiconductor device of claim 1, further comprising:
a high-concentration capacitor region of the second conductivity type having an impurity concentration higher than an impurity concentration of the capacitor region and being formed in a surface layer portion of the capacitor region,
wherein the trench is formed in the main surface so as to penetrate the capacitor region and the high-concentration capacitor region, and
wherein the embedded electrodes form the capacitive coupling with the capacitor region and the high-concentration capacitor region through the insulating film.

9. The semiconductor device of claim 1, further comprising:
a first wiring electrically connected to the at least one trench structure on the main surface; and
a second wiring electrically connected to the capacitor region on the main surface.

10. The semiconductor device of claim 1, further comprising:
a capacitive device region provided on the main surface; and
a region isolation structure formed on the main surface so as to electrically isolate the capacitive device region from other regions,
wherein the capacitor region is formed on the capacitive device region, and
wherein the at least one trench structure is formed on the capacitive device region.

11. The semiconductor device of claim 1, further comprising:
a transistor region provided on the main surface; and
a capacitive device region provided on the main surface,
wherein the capacitor region is formed on the capacitive device region, and
wherein the at least one trench structure is formed on the capacitive device region.

12. The semiconductor device of claim 11, wherein the capacitive device region has a plan-view area smaller than a plan-view area of the transistor region.

13. The semiconductor device of claim 11, wherein the transistor region includes:
a body region of the second conductivity type formed in the surface layer portion of the main surface; and
at least one trench gate structure including a gate trench formed in the main surface to penetrate the body region, a gate insulating film covering a wall surface of the gate trench, and gate electrodes embedded in the gate trench and disposed between portions of the gate insulating film.

14. The semiconductor device of claim 13, wherein the gate electrodes have a multi-electrode structure including a gate upper electrode embedded in the gate trench at an opening side and disposed between portions of the gate insulating film, and a gate lower electrode embedded in the gate trench at a bottom wall side and disposed between portions of the gate insulating film.

15. The semiconductor device of claim 14, wherein the gate upper electrode is embedded in the gate trench at the opening side with respect to a bottom portion of the body region so as to face the body region through the gate insulating film, and
wherein the gate lower electrode is embedded in the gate trench at the bottom wall side with respect to the bottom portion of the body region so as to face the semiconductor region through the gate insulating film.

16. The semiconductor device of claim 14, wherein the gate insulating film includes a gate upper insulating film covering the wall surface of the gate trench at the opening side, and a gate lower insulating film covering the wall surface of the gate trench at the bottom wall side with a thickness larger than a thickness of the gate upper insulating film,
wherein the gate upper electrode is embedded in the gate trench at the opening side and disposed between portions of the gate upper insulating film, and
wherein the gate lower electrode is embedded in the gate trench at the bottom wall side and disposed between portions of the gate lower insulating film.

17. The semiconductor device of claim 14, wherein the at least one trench gate structure includes a gate intermediate insulating film disposed between the gate upper electrode and the gate lower electrode.

18. The semiconductor device of claim 13, further comprising:
a source region of the first conductivity type formed in a region provided along the at least one trench gate structure at the surface layer portion of the body region.

19. The semiconductor device of claim 13, further comprising:
a high-concentration body region of the second conductivity type having an impurity concentration higher than an impurity concentration of the body region and being formed in a region provided along the at least one trench gate structure at the surface layer portion of the body region.

20. The semiconductor device of claim 13, wherein the at least one trench gate structure includes a plurality of trench gate structures formed at intervals in the main surface.
